(19) United States
(12) Patent Application Publication
(10) Pub. No.: US 2007/0045713 A1
(43) Pub. Date: Mar. 1, 2007

(54) SEMICONDUCTOR MEMORY DEVICE

(75) Inventors: Takashi ONO, Tokyo (JP); Narihisa FUJII, Tokyo (JP); Takashi YUDA, Tokyo (JP); Kenji OHNUKI, Tokyo (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/425,710

(22) Filed: Jun. 22, 2006

(30) Foreign Application Priority Data
Aug. 26, 2005 (JP) 2005-246824

(51) Int. Cl. H01L 29/788

(52) U.S. Cl. 257/315

(57) ABSTRACT

A semiconductor memory device with improved characteristics in a reading operation is disclosed. This semiconductor memory device has: a first diffused region disposed within a semiconductor substrate; a gate dielectric spaced apart from the first diffused region, and overlying the semiconductor substrate; a gate electrode overlying the gate dielectric; a first multilayer disposed between the first diffused region and the gate dielectric, and overlying the semiconductor substrate; and a third diffused region disposed adjacent to the first multilayer within the semiconductor substrate, and doped with dopant at lower concentration than the first diffused region. The first multilayer accumulates a first charge (electron, for example), and subsequently accumulates a second charge (hole, for example) having a polarity that is opposite to the first charge, in a programming operation.

### BACKGROUND OF THE INVENTION

1. Field of the Invention

The present invention relates to a semiconductor memory device.

2. Background Information

U.S. Pat. No. 5,408,115 (Pages 1-12, FIG. 1-6), U.S. Pat. No. 6,255,166 (Pages 1-20, FIG. 1-18), and Japanese Patent Publication JP-A-H06-309881 (Pages 1-4, FIG. 1-4) disclose a MONOS (Metal-Oxide-Nitride-Oxide-Semiconductor) type non-volatile memory cell in which electrodes are disposed on an ONO (Oxide-Nitride-Oxide) film. Japanese Patent Publication JP-A-2005-64295 (Pages 1-22, FIG. 1-17) discloses a MONOS type non-volatile memory cell in which electrodes are not disposed on an ONO film.

A structure not having electrodes on an ONO film has advantages in easiness of control, cost, and the like, in comparison with a structure that does have electrodes on an ONO film.

However, a MONOS type non-volatile memory cell disclosed in Japanese Patent Publication JP-A-2005-64295 has a disadvantage in that the difference in the amount of current used for reading before programming to an ONO film and that used for reading after programming may not be distinct enough to easily discriminate between a data “0” and data “1”, since the memory cell does not have electrodes on the ONO film.

In view of the above, it will be apparent to those skilled in the art from this disclosure that there exists a need for an improved semiconductor memory device in which the difference in the read current before programming to an ONO film and the read current after programming will become distinct enough to easily discriminate between a data “0” and data “1”. This invention addresses this need in the art as well as other needs, which will become apparent to those skilled in the art from this disclosure.

### SUMMARY OF THE INVENTION

The present invention may include: a first diffused region disposed within a semiconductor substrate; a gate dielectric spaced apart from the first diffused region, and overlying the semiconductor substrate; a gate electrode overlying the gate dielectric; a first multilayer disposed between the first diffused region and the gate dielectric, and overlying the semiconductor substrate; and a third diffused region disposed adjacent to the first multilayer within the semiconductor substrate, and doped with dopant at a lower concentration than the first diffused region. In this semiconductor memory device, the first multilayer will accumulate a first charge, and subsequently accumulate a second charge having a polarity that is opposite to the first charge, in a programming operation.

The first charge is accumulated in the first multilayer. This allows the read current to be large when the first multilayer is not programmed. Moreover, the second charge is accumulated in order to program after the first charge is accumulated. This allows the read current to be small when the first multilayer is programmed.

Therefore, in this semiconductor memory device, the difference between the current when the first multilayer is not programmed and the current when the first multilayer is programmed will be large.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a circuit diagram of a reference semiconductor memory device;

FIG. 2 is an equivalent circuit diagram of a memory cell in a reference semiconductor memory device;

FIG. 3 is a cross-sectional view of a structure of a memory cell in a reference semiconductor memory device;

FIG. 4 illustrates the read current characteristics of a memory cell in a reference semiconductor memory device;

FIG. 5A is a cross-sectional view of the semiconductor memory device structure used to explain a fabrication process;

FIG. 5B is a cross-sectional view of the semiconductor memory device structure used to explain a fabrication process;

FIG. 5C is a cross-sectional view of the semiconductor memory device structure used to explain a fabrication process;

FIG. 6A is a cross-sectional view of the semiconductor memory device structure used to explain a fabrication process;

FIG. 6B is a cross-sectional view of the semiconductor memory device structure used to explain a fabrication process;

FIG. 7A is a cross-sectional view of the semiconductor memory device structure used to explain a fabrication process;

FIG. 7B is a cross-sectional view of the semiconductor memory device structure used to explain a fabrication process;

FIG. 8A is a cross-sectional view of the semiconductor memory device structure used to explain a fabrication process;

FIG. 8B is a cross-sectional view of the semiconductor memory device structure used to explain a fabrication process;

FIG. 9A is a cross-sectional view of the semiconductor memory device structure used to explain a fabrication process;

FIG. 9B is a cross-sectional view of the semiconductor memory device structure used to explain a fabrication process;

FIG. 10A is a cross-sectional view of the semiconductor memory device structure used to explain a fabrication process;

FIG. 10B is a cross-sectional view of the semiconductor memory device structure used to explain a fabrication process;

FIG. 11A is a cross-sectional view of the semiconductor memory device structure used to explain a fabrication process;

FIG. 11B is a cross-sectional view of the semiconductor memory device structure used to explain a fabrication process;

FIG. 12 is a circuit diagram of a semiconductor memory device according to a first embodiment;

FIG. 13 is a cross-sectional view of the semiconductor memory device structure according to the first embodiment, illustrating an erasing operation;

FIG. 14 is a cross-sectional view of the semiconductor memory device structure according to the first embodiment, illustrating a programming operation;

FIG. 15 illustrates the read current characteristics of a memory cell in a semiconductor memory device according to the first embodiment;

FIG. 16 is a cross-sectional view of the semiconductor memory device structure according to a second embodiment, illustrating an erasing operation;

FIG. 17 is a cross-sectional view of the semiconductor memory device structure according to the second embodiment, illustrating a programming operation;

FIG. 18 is a cross-sectional view of the semiconductor memory device structure according to the third embodiment, illustrating an erasing operation;

FIG. 19 is a cross-sectional view of the semiconductor memory device structure according to the third embodiment, illustrating a programming operation;

FIG. 20 is a cross-sectional view of the semiconductor memory device structure according to a fourth embodiment, illustrating an erasing operation; and

FIG. 21 is a cross-sectional view of the semiconductor memory device structure according to the fourth embodiment, illustrating a programming operation;

### DETAILED DESCRIPTION OF THE PREFERRED EMBODIMENTS

In order to make it easier to understand embodiments of the present invention, a reference semiconductor memory device will be described before explanation of the embodiments.

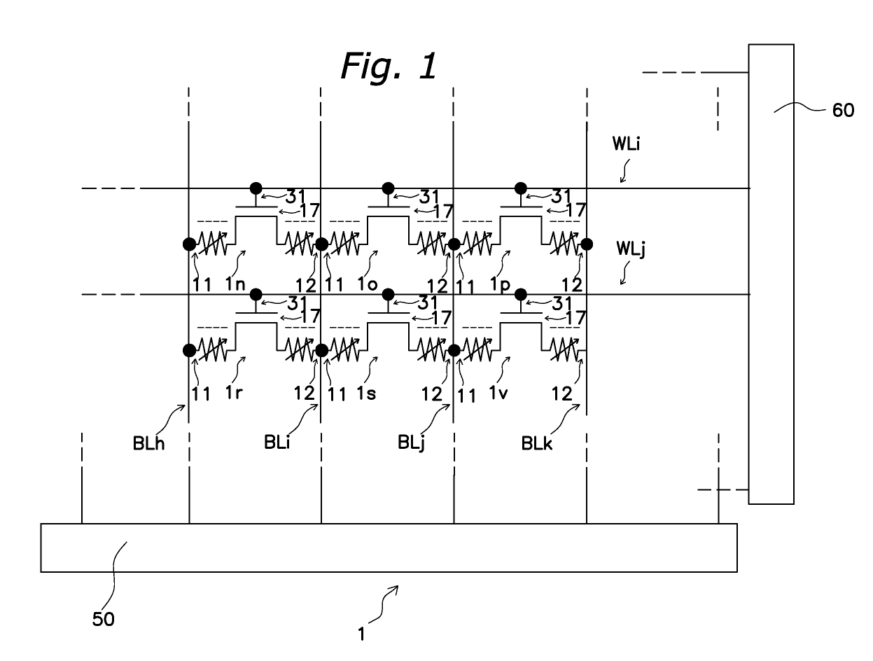

FIG. 1A is a circuit diagram of a reference semiconductor memory device 1 (reference device 1). As shown in FIG. 1A, semiconductor memory device 1 is mainly comprised of a plurality of memory cells 1n, 1o, 1p, . . . , 1r, 1s, 1v, . . . , first voltage applying section 60, and second voltage applying section 50.

Memory cells 1n, 1o, 1p, . . . are arranged in a matrix, each of which has a gate electrode 31, a first diffused region 11, a second diffused region 12, and a channel forming region 17. Gate electrode 31 of each memory cell is connected to word lines WLi, WLj, . . . . First diffused region 11 and second diffused region 12 of memory cells 1n, 1o, 1p, . . . are connected to bit lines BLh, BLi, BLj, BLk, . . . . Channel forming region 17 of each memory cell is connected to first diffused region 11 and second diffused region 12. One of the first diffused region 11 and second diffused region 12 operates as a source electrode, while the other operates as a drain electrode.

First voltage applying section 60 is connected to gate electrodes 31 of memory cells 1n, 1o, 1p, . . . by way of word lines WLi, WLj . . . , thereby applying gates voltages VWi1, VWj1, . . . to gate electrodes 31 of memory cells 1n, 1o, 1p, . . . .

Second voltage applying section 50 is connected to first diffused region 11 and second diffused region 12 of memory cells 1n, 1o, 1p, . . . by way of bit lines BLh, BLi, BLj, BLk, . . . , thereby applying source voltages VBh1, . . . to one of the first diffused region 11 and second diffused region 12, and applying drain voltages VBi1, . . . to the other.

Operations of semiconductor memory device 1 will now be roughly described. Memory cells 1n, 1o, 1p, . . . receive gate voltages VWi1, VWj1, . . . from first voltage applying section 60 by way of word lines WLi, WLj . . . . When gate voltages VWi1, VWj1, . . . are H(high)-level, channel forming regions 17 of corresponding memory cells 1n, 1o, 1p, . . . are placed in an ON-state, which enables current to flow between first diffused region 11 and second diffused region 12. When gate voltages VWi1, VWj1, . . . are L(low)-level, channel forming regions 17 of corresponding memory cells 1n, 1o, 1p, . . . are placed in an OFF-state, which enables little or no current to flow between first diffused region 11 and second diffused region 12.

Meanwhile, memory cells 1n, 1o, 1p, . . . receive source voltages VBh1, . . . and drain voltages VBi1, . . . from second voltage applying section 50 by way of bit lines BLh, BLi, BLj, BLk, . . . .

A situation will now be considered in which source voltages VBh1, . . . are applied to first diffused regions II of memory cells 1n, 1o, 1p, . . . by way of bit lines BLh, . . . , and drain voltages VBi1, . . . are applied to second diffused region 12 of memory cells 1n, 1o, 1p, . . . by way of bit lines BLi, . . . . In this situation, when source voltages VBh1, . . . are higher than drain voltages VBi1, . . . , drain current Ids flows from first diffused region 11 to second diffused region 12 in the memory where the applied gate voltage is H-level and where the channel forming region 17 is in an ON-state. When source voltages VBh1, . . . are lower than drain voltages VBi1, . . . , drain current Ids flows from second diffused region 12 to first diffused region 11 in memory cells where the applied gate voltage is H-level and where the channel forming region 17 is in an ON-state. In this way, an erasing operation, a programming operation, and a reading operation are performed for selected memory cells through word lines WLi, . . . and bit lines BLh, . . . by first voltage applying section 60 and second voltage applying section 50. Operations may be explained similarly in a situation in which drain voltages VBh1, . . . are applied to first diffused regions 11 of memory cells 1n, 1o, 1p, . . . by way of bit lines BLh, . . . , and source voltages VBi1, . . . are applied to second diffused regions 12 of memory cells 1n, 1o, 1p, . . . by way of bit lines BLi, . . .

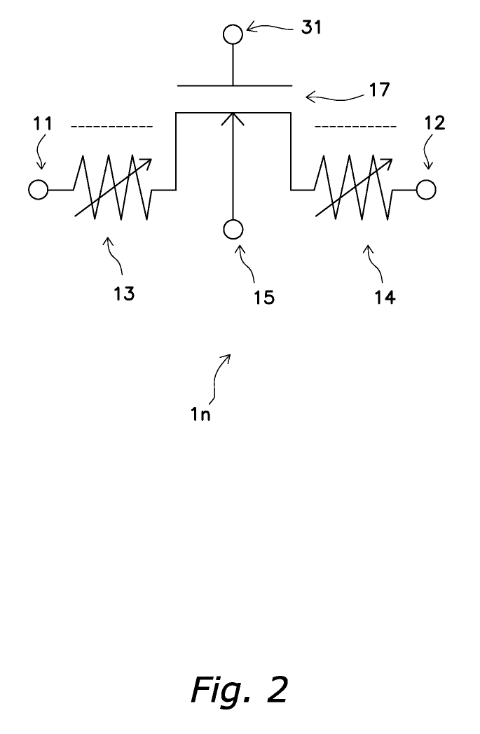

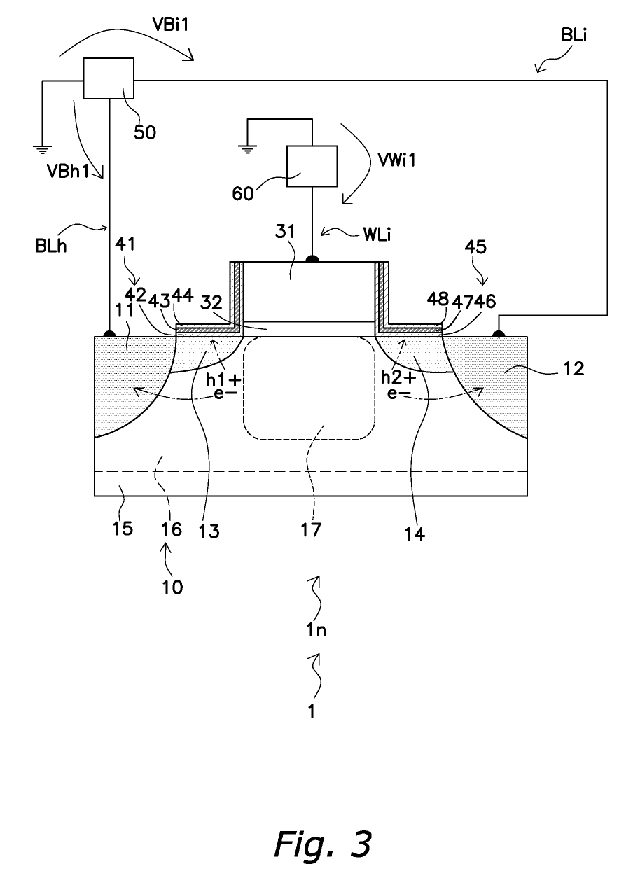

A memory cell in semiconductor memory device 1 will now be described in detail with reference to FIG. 2 and FIG. 3. FIG. 2 is an equivalent circuit diagram of a memory cell. FIG. 3 is a cross-sectional view of a structure of a memory cell.

Referring to FIG. 2 and FIG. 3, memory cell 1n, as an example, is mainly comprised of a first diffused region 11, a gate dielectric 32, a gate electrode 31, a first multilayer 41, a third diffused region 13, a second diffused region 12, a second multilayer 45, a fourth diffused region 14, a P-well region 16, and a channel forming region 17, resulting in a MOSFET (Metal Oxide Semiconductor Field Effect Transistor).

Referring to FIG. 3, first diffused region 11 is formed in semiconductor substrate 10. First diffused region 11 is heavily doped with an N-type dopant by implanting Arsenic (As) or Phosphorus (P) at a concentration of 10E20 atoms/cm³, for example, and functions as a source electrode or a drain electrode. First diffused region 11 receives either source voltage VBh1 or drain voltage VBh1.

Gate dielectric 32 is formed on semiconductor substrate 10, and is spaced apart from first diffused region 11. Gate dielectric 32 is a film for insulating gate electrode 31 from semiconductor substrate 10.

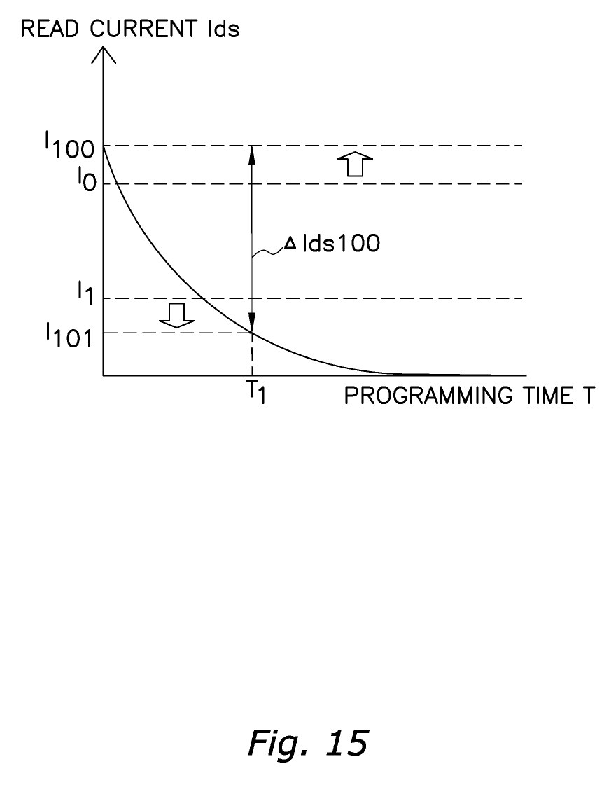

Gate electrode 31 overlies gate dielectric 32. Gate electrode 31 is a conductive film having a polysilicon film 33 and a silicide film 34 layered together (see FIG. 15A, FIG. 15B). Gate electrode 31 receives gate voltage VWi1.

First multilayer 41 overlies semiconductor substrate 10 between first diffused region 11 and gate dielectric 32. First multilayer 41 is mainly comprised of a first dielectric layer 42, a charge accumulation layer 43, and a second dielectric layer 44. First dielectric layer 42 insulates charge accumulation layer 43 from semiconductor substrate 10. Charge accumulation layer 43 accumulates a charge as a hole or an electron. Second dielectric layer 44 insulates charge accumulation layer 43 from the upper film thereof. Namely, charge accumulation layer 43 is sandwiched between first dielectric layer 42 and second dielectric layer 44 so as to retain a charge as a hole or an electron in a stable manner. First dielectric layer 42 and second dielectric layer 44 are made of silicon dioxide as a main component, while charge accumulation layer 43 is made of silicon nitride as a main component.

Third diffused region 13 is formed within semiconductor substrate 10 in the vicinity of first multilayer 41. Third diffused region 13 is more lightly doped with an N-type dopant than first diffused region 11 (at a concentration of 10E17 atoms/cm³, for example). Third diffused region 13 operates as a variable resistor.

Second diffused region 12 is disposed on the side of gate electrode 31 opposite to first diffused region 11 within semiconductor substrate 10. Second diffused region 12 is heavily doped with an N-type dopant by implanting Arsenic (As) or Phosphorus (P) at concentration of 10E20 atoms/cm³, for example, and functions as a source electrode or a drain electrode. Second diffused region 12 receives either source voltage VBi1 or drain voltage VBi1.

Second multilayer 45 overlies semiconductor substrate 10 between second diffused region 12 and gate dielectric 32. Second multilayer 45 is mainly comprised of a first dielectric layer 46, a charge accumulation layer 47, and a second dielectric layer 48. First dielectric layer 46 insulates charge accumulation layer 47 from semiconductor substrate 10. Charge accumulation layer 47 accumulates a charge as a hole or an electron. Second dielectric layer 48 insulates charge accumulation layer 47 from its upper film. Namely, charge accumulation layer 47 is sandwiched between first dielectric layer 46 and second dielectric layer 48 so as to retain a charge as a hole or an electron in a stable manner. First dielectric layer 46 and second dielectric layer 48 are made of silicon dioxide as a main component, while charge accumulation layer 47 is made of silicon nitride as a main component.

Fourth diffused region 14 is formed within semiconductor substrate 10 in the vicinity of second multilayer 45. Fourth diffused region 14 is more lightly doped with an N-type dopant than second diffused region 12 (at concentration of 10E17 atoms/cm³, for example). Fourth diffused region 14 operates as a variable resistor.

P-well region 16 is more heavily doped with a P-type dopant by implanting Boron (B) than back gate 15 within semiconductor substrate 10. Channel forming region 17 is located between first diffused region 11 and second diffused region 12 within P-well region 16. That is, an N-channel is formed in a portion adjacent to gate electrode 31 in channel forming region 17, when a positive voltage is applied to gate electrode 31.

The structure of memory cell 1n was described above as an example. The structures of other memory cells 1o, 1p, . . . are identical to those of memory cell 1n.

Operations of memory cell 1n, as an example, will now be described with reference to TABLE 1 below. Operations of other memory cells 1o, 1p, . . . are identical to those of memory cell 1n. FIG. 3 illustrates an erasing operation.

TABLE 1

| | Drain voltage | Gate voltage | Source voltage |
|---|---|---|---|
| Erase | +Vde1 | −Vge1 | Open |
| Program | +Vdw1 | +Vgw1 | 0 |
| Read | 0 | +Vgr1 | +Vsr1 |

First, an erasing operation will be described. In an erasing operation of first multilayer 41, gate voltage VWi1=−Vge1 (−3V, for example) is applied to gate electrode 31 by way of word line WLi. Drain voltage VBh1=+Vde1 (7V, for example) is applied to first diffused region 11, while second diffused region 12 (source voltage VBi1) is set open. Then, a high electric field is generated between gate electrode 31 and a drain electrode (first diffused region 11), and accordingly, an inter-band tunneling current is generated in response to a large change in the energy band at the edge of the drain electrode (first diffused region 11). The inter-band tunneling current flows through P-well region 16, directed to back gate 15 which is grounded, and generates hot-holes. As shown in FIG. 3, the hot-holes (h1+) are attracted by gate voltage VWi1=−Vge1, and injected to charge accumulation layer 43 of first multilayer 41 at a certain neutralization amount. A neutralization amount is the amount of charge needed for neutralizing accumulated electrons. As a result, the injected hot-holes and electrons accumulated in charge accumulation layer 43 are offset such that the charges accumulated in charge accumulation layer 43 become substantially zero. In this way, data “1” previously programmed (written) in charge accumulation layer 43 of first multilayer 41 will be erased.

In an erasing operation of second multilayer 45, gate voltage VWi1=−Vge1 (−3V, for example) is applied to gate electrode 31 by way of word line VLi. First diffused region 11 (source voltage VBh1) is set open, while drain voltage VBi1=+Vde1 (7V, for example) is applied to second diffused region 12. Then, a high electric field is generated between gate electrode 31 and a drain electrode (second diffused region 12), and accordingly, an inter-band tunneling current is generated in response to a large change in the energy band at the edge of the drain electrode (second diffused region 12). The inter-band tunneling current flows through P-well region 16, directed to back gate 15 which is grounded, and generates hot-holes. As shown in FIG. 3, the hot-holes (h2+) are attracted by gate voltage VWi1=−Vge1, and injected to charge accumulation layer 47 of second multilayer 45 at a certain neutralization amount. The neutralization amount is the amount of charge needed for neutralizing accumulated electrons. As a result, the injected hot-holes and electrons accumulated in charge accumulation layer 47 are offset such that the charges accumulated in charge accumulation layer 47 become substantially zero. In this way, data “1” previously programmed (written) in charge accumulation layer 47 of second multilayer 45 will be erased.

Secondly, a programming operation will be described. In a programming operation of first multilayer 41, gate voltage VWi1=+Vgw1 (8V, for example) is applied to gate electrode 31 by way of word line WLi. Drain voltage VBh1=+Vdw1 (7V, for example) is applied to first diffused region 11, while source voltage VBi1=0 is applied to second diffused region 12. Then, hot electrons are generated in such a way that electrons directed from a source electrode (second diffused region 12) to a drain electrode (first diffused region 11) are accelerated in a resistor changing region (third diffused region 13) adjacent to the drain electrode. The hot electrons are attracted by gate voltage VWi1=+Vgw1, and injected into charge accumulation layer 43 of first multilayer 41, thereby programming data “1” in charge accumulation layer 43 of first multilayer 41. Meanwhile, where gate voltage VWi1=0, hot electrons are not injected into charge accumulation layer 43 of first multilayer 41, and thus, data “1” is not programmed (data “0” is programmed) in charge accumulation layer 43 of first multilayer 41.

In a programming operation of second multilayer 45, gate voltage VWi1=+Vgw1 (8V, for example) is applied to gate electrode 31 by way of word line WLi. Source voltage VBh1=0 is applied to first diffused region 11, while drain voltage VBi1=+Vdw1 (7V, for example) is applied to second diffused region 12. Then, hot electrons are generated in such a way that electrons directed from a source electrode (first diffused region 11) to a drain electrode (second diffused region 12) are accelerated in a resistor changing region (fourth diffused region 14) adjacent to the drain electrode. The hot electrons are attracted by gate voltage VWi1=+Vgw1, and injected into charge accumulation layer 47 of second multilayer 45, thereby programming data “1” in charge accumulation layer 47 of second multilayer 45. Meanwhile, where gate voltage VWi1=0, hot electrons are not injected into charge accumulation layer 47 of second multilayer 45, and thus, data “1” is not programmed (data “0” is programmed) in charge accumulation layer 47 of second multilayer 45.

The relationship between an erasing operation and a programming operation will now be described. In an erasing operation of first multilayer 41, charges accumulated in charge accumulation layer 43 become substantially zero. In a programming operation of first multilayer 41, hot electrons are injected to first multilayer 41 in order to program after the erasing operation.

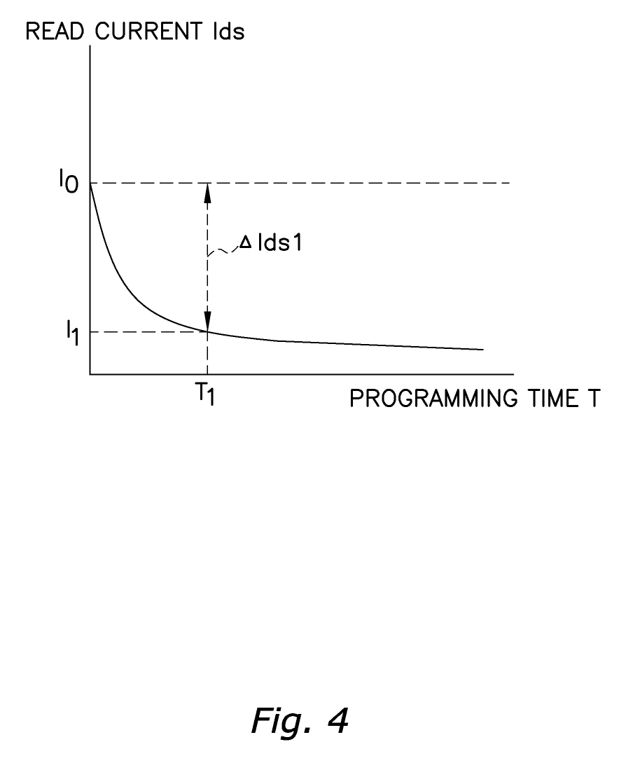

Namely, when data “1” is programmed in charge accumulation layer 43 of first multilayer 41, it is hard for current (electrons) to flow through third diffused region 13 due to the negative charges (electrons) in charge accumulation layer 43, and the resistance of third diffused region 13 will be high. Thus, as shown in FIG. 4, read current Ids is I1 (20 μA, for example) when the programming time is T1 (10 μs, for example). On the other hand, when data “1” is not programmed (data “0” is programmed) in charge accumulation layer 43 of first multilayer 41, current easily flows through third diffused region 13 due to a zero charge (no charge) in charge accumulation layer 43, and the resistance of third diffused region 13 will be relatively low. Thus, as shown in FIG. 4, read current Ids will be I0 (30 μA, for example).

Therefore, the difference ΔIds1 (10 μA, for example) is not sufficiently large between read current Ids=I0 (30 μA, for example) when no programming operations are performed (data “0” is programmed) for first multilayer 41, and current Ids=I1 (20 μA, for example) when a programming operation is performed for first multilayer 41. Accordingly, it may be difficult to discriminate between data “1” and data “0” based on read current Ids, or, it may take time to discriminate between data “1” and data “0” based on read current Ids.

In an erasing operation of second multilayer 45, charges accumulated in charge accumulation layer 47 become substantially zero. In a programming operation of second multilayer 45, hot electrons are injected and programmed after the erasing operation.

Namely, when data “1” is programmed in charge accumulation layer 47 of second multilayer 45, it is hard for current (electrons) to flow through fourth diffused region 14 due to the negative charges (electrons) in charge accumulation layer 47, and the resistance of fourth diffused region 14 will be high. Thus, as shown in FIG. 4, read current Ids is I1 (20 μA, for example) when the programming time is T1 (10 μA, for example). On the other hand, when data “1” is not programmed (data “0” is programmed) in charge accumulation layer 47 of second multilayer 45, current easily flows through fourth diffused region 14 due to a zero charge (no charge) in charge accumulation layer 47, and the resistance of fourth diffused region 14 will be relatively low. Thus, as shown in FIG. 4, read current Ids will be I0 (30 μA, for example).

Therefore, the difference ΔIds1 (10 μA, for example) is not sufficiently large between read current Ids=I0 (30 μA, for example) when no programming operations are performed (data “0” is programmed) for second multilayer 45, and current Ids=I1 (20 μA, for example) when a programming operation is performed for second multilayer 45. Accordingly, it may be difficult to discriminate between data “1” and data “0” based on read current Ids, or, it may take time to discriminate between data “1” and data “0” based on read current Ids.

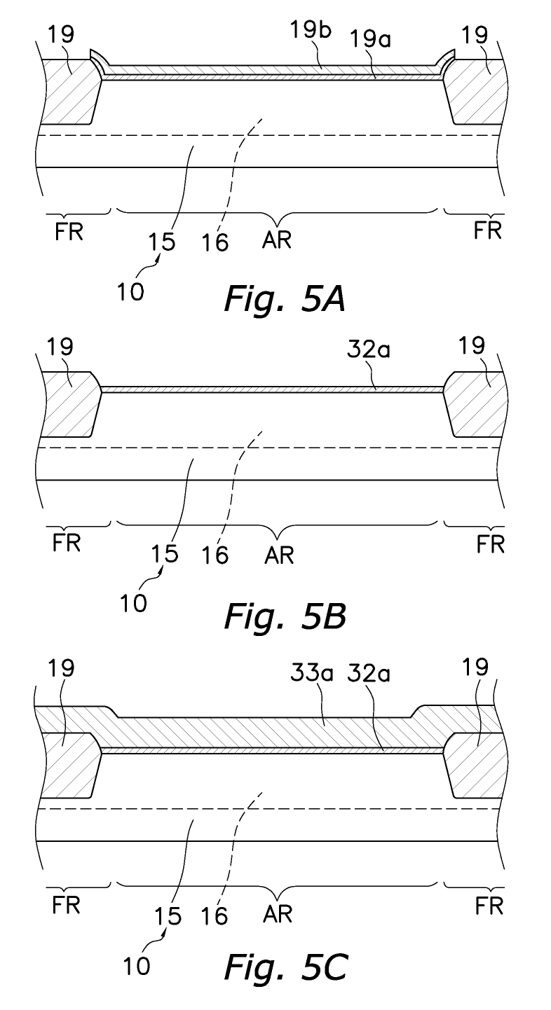

A fabrication method of semiconductor memory device 1 will now be described with reference to FIGS. 5 to 11. FIGS. 5 to 11 are cross-sectional views of semiconductor memory device 1 used to explain the fabrication process.

First, semiconductor substrate 10 is provided in which a P-type dopant is lightly doped by implanting Boron (B). One side of a surface of semiconductor substrate 10 is heavily doped with a P-type dopant by implanting Boron (B), resulting in P-well region 16. The other side of the surface of semiconductor substrate 10 is back gate 15. One side of the surface of semiconductor substrate 10 in which P-well region 16 is disposed is thermal-oxidized to form a silicon dioxide film of approximately 100 angstrom thickness, for example. Then, a silicon nitride film of 200 angstroms thickness is formed on the silicon dioxide film by a conventional CVD process.

In the following step, a given photoresist is spin-coated on the silicon nitride film. A resist film (not shown) will be formed following an exposure process and a development process, and will have an opening on a region within which an isolation dielectric 19 will be disposed in a later step. Then, the silicon dioxide film and the silicon nitride film are patterned with the resist film used as a mask. A patterned silicon dioxide film 19a and a silicon nitride film 19b overlie a region where isolation dielectric 19 is not disposed, while semiconductor substrate 10 is exposed in a region where isolation dielectric 19 will be disposed. The fabrication process will not be significantly affected if the silicon dioxide film partially resides in the region where isolation dielectric 19 will be disposed. Patterned silicon nitride film 19b functions as a protection film for protecting the region where isolation dielectric 19 will not be disposed, that is, an active region AR. The patterned silicon dioxide film 19a functions as an adhesion layer for adhering semiconductor substrate 10 and patterned silicon nitride film 19b together. In patterning silicon nitride film 19b, a conventional dry etching or wet etching is applied. After patterning silicon nitride film 19b and silicon dioxide film 19a, the resist film is removed.

Then, a thermal oxidation process is performed on the surface of semiconductor substrate 10, resulting in the isolation dielectric 19 on the surface of semiconductor substrate 10 as shown in FIG. 5A. Isolation dielectric 19 sections the surface of semiconductor substrate 10 into an active region AR and a field region FR.

After removing silicon nitride film 19b, the surface of semiconductor substrate 10 is wet oxidized. Accordingly, as shown in FIG. 5B, a silicon dioxide film 32a (first dielectric film) is formed. Silicon dioxide film 32a is a dielectric film which will be processed to form gate dielectric 32 in a later step. It is to be noted that silicon dioxide film 32a may be formed after entirely removing silicon dioxide film 19a in the step shown in FIG. 5B.

In the following step, as shown in FIG. 5C, a polysilicon film 33a of approximately 4,500 angstrom thickness, for example, is formed to overlie isolation dielectric 19 and silicon dioxide film 32a by means of CVD (chemical vapor deposition) or sputtering. Polysilicon film 33a is doped with an N-type dopant by implanting Phosphorus (P), for example, and accordingly obtains conductivity.

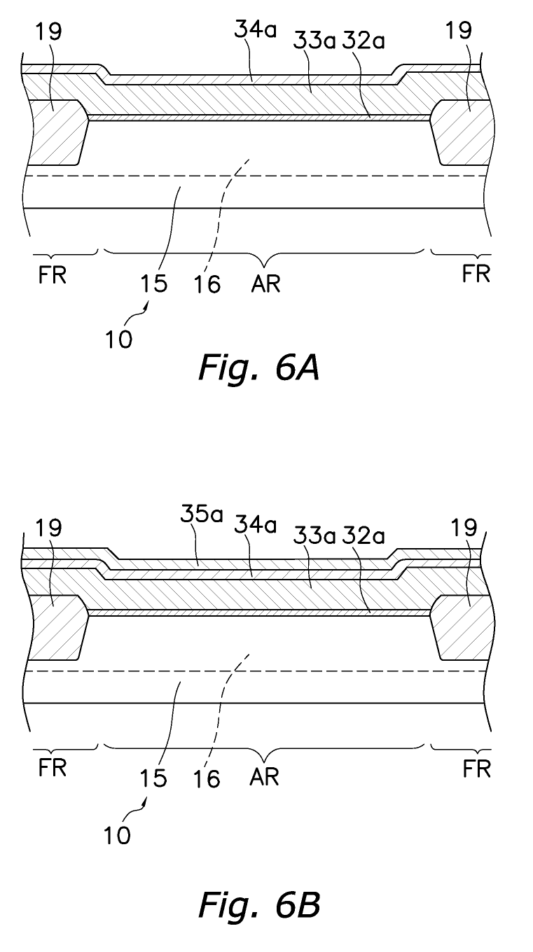

In the following step, as shown in FIG. 6A, a silicide film 34a of approximately 500 angstrom thickness, for example, is formed to overlie polysilicon film 33a by means of CVD or sputtering. A WSix film, that is, a tungsten-silicide film is applied for silicide film 34a. Polysilicon film 33a and silicide film 34a are conductive films which will be processed to form gate electrode 31 in a later step.

In the following step, as shown in FIG. 6B, a silicon dioxide film 35a of approximately 1,000 angstrom thickness, for example, is formed to overlie silicide film 34a by means of CVD. The silicon dioxide film 35a is a NSG (Nondoped Silicate Glass) film, and will be processed to form an oxide film 35 (mask) as a hard mask in patterning polysilicon film 33a and silicide film 34a in a later step.

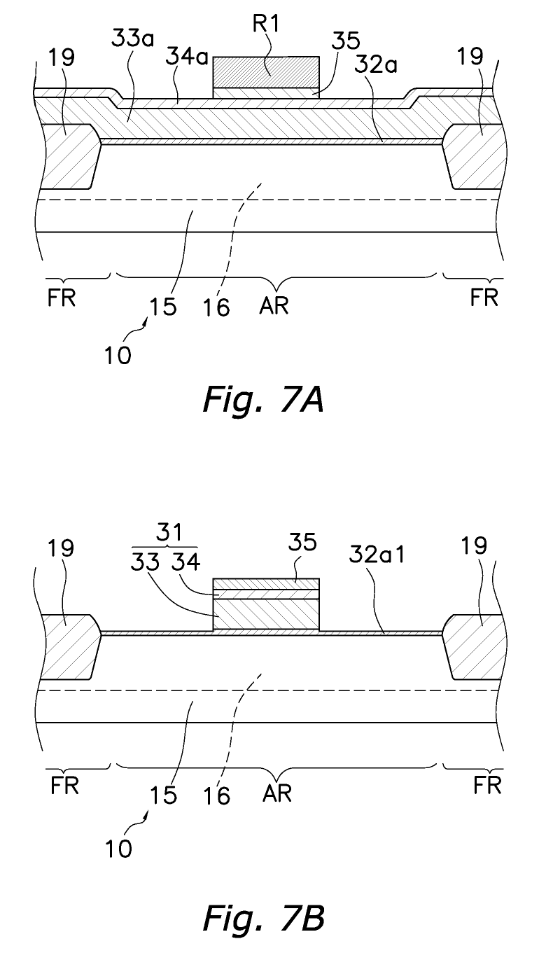

A given photoresist is spin-coated on silicon dioxide film 35a. After performing a conventional exposure process and development process, a resist film R1 is formed on a region on which gate electrode 31 will be disposed in a later step. Then, silicon dioxide film 35a is patterned by means of a conventional etching technology with resist film R1 used as a mask, to form oxide film 35 (mask), as shown in FIG. 7A. After patterning silicon dioxide film 35a, resist film R1 is removed.

Silicide film 34a and polysilicon film 33a are patterned by means of a conventional etching technology with oxide film 35 (mask) used as a hard mask, to form polysilicon film 33 and silicide film 34, as shown in FIG. 7B. Namely, gate electrode 31 having a total thickness of approximately 3,000 angstroms is formed.

It is to be noted that, in forming gate electrode 31 by patterning (see FIG. 7B), silicon dioxide 32a is etched (over-etched) such that semiconductor substrate 10 is not exposed, in order to prevent a short circuit due to film residue. Since the selectivity of polysilicon film 33a and silicon dioxide film 32a is roughly 10 to 150 in the above-mentioned dry etching, the silicon dioxide film 32a underlying polysilicon film 33a is also partially etched. Accordingly, an exposed portion of silicon dioxide film 32a will become thinner (see silicon dioxide film 32a l in FIG. 7B).

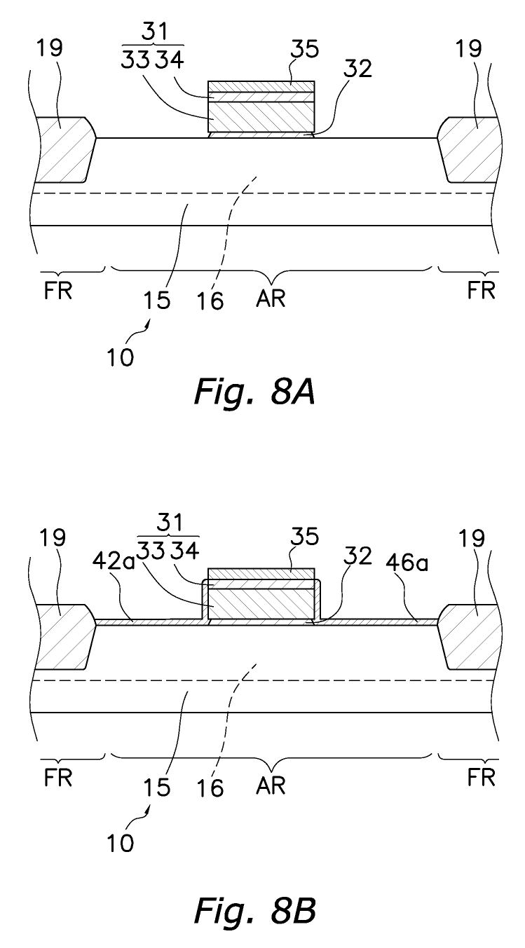

Then, as shown in FIG. 8A, the thinner portion of silicon dioxide film 32a l is removed, and the corresponding surface of semiconductor substrate 10 becomes exposed. Wet etching is applied in removing the thinner portion of silicon dioxide film 32a1, such that damage is prevented for semiconductor substrate 10, and such that only the exposed portion of silicon dioxide film 32a is removed. This wet etching method applies a hydrofluoric acid solution at a concentration of approximately 5% at approximately 25 degrees Centigrade, for example. The selectivity of the silicon dioxide film 32a1 to a silicon substrate (semiconductor substrate 10) will become large when the above method is employed, and thus, damage will be prevented for semiconductor substrate 10, and only the exposed portion of silicon dioxide film 32a will be removed.

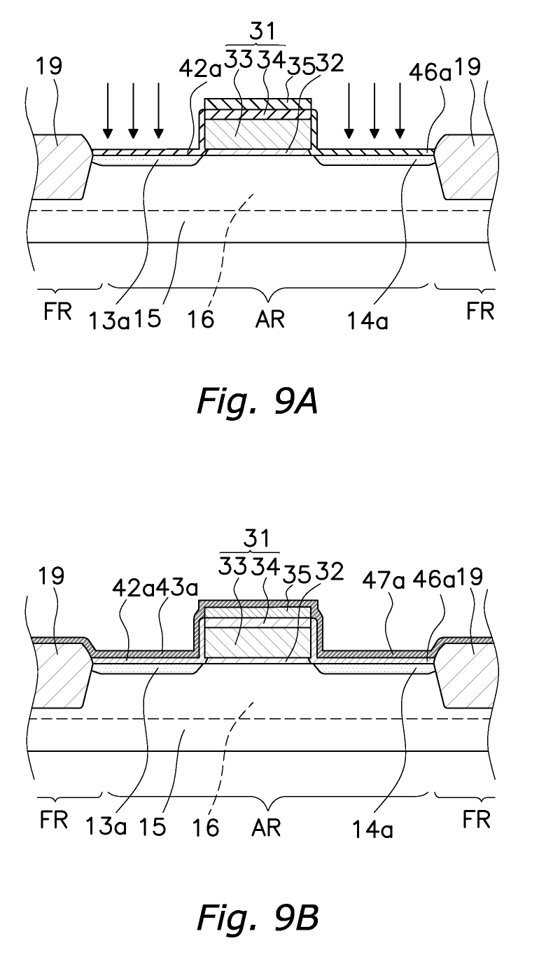

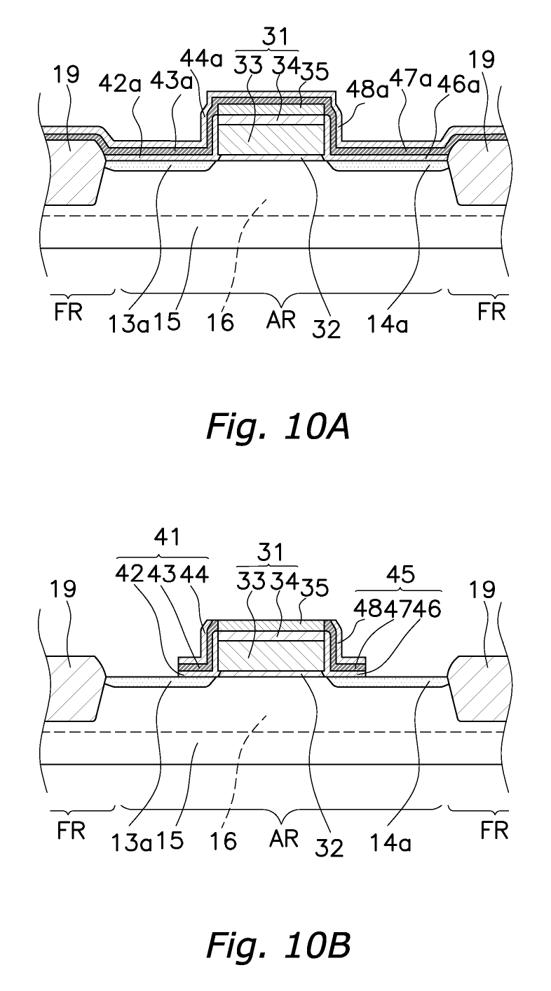

In the following step, as shown in FIG. 8B, silicon dioxide films (second dielectric film) 42a, 46a of approximately 70 angstrom thickness, for example, are formed by means of a thermal oxidation process, for example, to overlie the side portions of gate electrode 31 and the surface of semiconductor substrate 10 between isolation dielectric 19 and gate electrode 31. The silicon dioxide films 42a, 46a will be processed to form first dielectric layer 42 of first multilayer 41 and first dielectric layer 46 of second multilayer 45 in a later step (see FIG. 10B). The silicon dioxide films 42a, 46a function as protection films for preventing channeling during ion implantation and outdiffusion in a thermal activation process performed in a later step (see FIG. 9A) in which third diffused region 13 and fourth diffused region 14 will be formed.

As explained above, silicon dioxide films 42a, 46a are formed as new dielectric films after removing silicon dioxide film 32a l, the insulation characteristics of which are deteriorated by plasma etching the pattering gate electrode 31. Thus, dielectric films in which the insulation characteristics thereof are not deteriorated are applied for first dielectric layer 42 of first multilayer 41 and first dielectric layer 46 of second multilayer 45. This allows charge accumulation layers 43, 47 overlying first dielectric films 42, 26 to retain fine charge residing characteristics. Further, in removing the thinner portion of silicon dioxide film 32a1, a method (wet etching using hydrofluoric acid solution, for example) is applied to minimize damage in semiconductor substrate 10, thereby preventing semiconductor memory device 1 from deterioration.

Then, as shown in FIG. 9A, ion implantation is performed with isolation dielectric 19 and gate electrode 31 used as a mask, to form diffused regions 13a, 14a between isolation dielectric 19 and gate electrode 31. In this ion implantation, a P-type dopant is doped by implanting Boron (B) at relatively low concentration of approximately 10E17 atoms/cm³, for example.

In the following step, as shown in FIG. 9B, silicon nitride films (third dielectric film) 43a, 47a of approximately 100 angstrom thickness, for example, are formed by means of CVD, for example, to overlie isolation dielectric 19, oxide film 35 (mask), and silicon dioxide films 42a, 46a. The silicon nitride films 43a, 47a will be processed to form charge accumulation layer 43 of first multilayer 41 and charge accumulation layer 47 of second multilayer 45 in a later step.

Then, as shown in FIG. 10A, silicon dioxide films 44a, 48a of approximately 50 angstrom thickness, for example, are formed by means of CVD, for example, to wholly overlie silicon nitride films 43a, 47a. The silicon dioxide films 44a, 48a will be processed to form second dielectric layer 44 of first multilayer 41 and second dielectric layer 48 of second multilayer 45 in a later step.

Silicon dioxide films 44a, 48a, silicon nitride films 43a, 47a, and silicon dioxide films 42a, 46a are now dry anisotropic etched in order. Accordingly, as shown in FIG. 10B, first multilayer 41 and second multilayer 45 are formed to extend along the surface of semiconductor substrate 10 from the side surfaces of gate electrode 31.

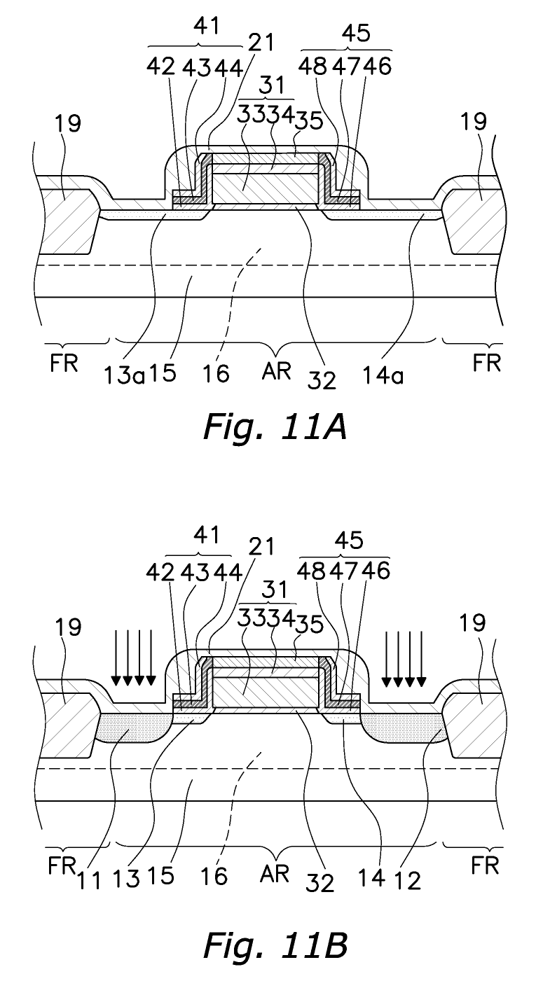

In the following step, as shown in FIG. 11A, protection film 21 of approximately 500 angstrom thickness, for example, are formed by CVD, for example, to overlie isolation dielectric 19, oxide film 35 (mask), first multilayer 41, and second multilayer 45. The protection film 21, which is a silicon dioxide film, for example, prevents channeling in ion implantation and outdiffusion in a thermal activation process during a following step (see FIG. 11B) in which first diffused region 11 and second diffused region 12 will be formed.

Then, as shown in FIG. 9A, ion implantation is performed with isolation dielectric 19, gate electrode 31, first multilayer 41, and second multilayer 45 used as a mask, to form first diffused region 11 and second diffused region 12 between second multilayer 45 and isolation dielectric 19. In this ion implantation, an N-type dopant is doped by implanting Arsenic (As) or Phosphorus (P) at relatively high concentration of approximately 10E20 atoms/cm³, for example.

Next, an interlayer dielectric film (not shown) is formed to overlie protection film 21. Conventional photolithography and etching being applied, a contact (not shown) is formed within the interlayer dielectric film to partially expose the top surfaces of gate electrode 31, first diffused region 11, and second diffused region 12. Then, a conductor such as tungsten (W) is filled in the contact. Finally, after patterning upper layer conductors (not shown) including Aluminum (Al) or Cupper (Cu) or the like on the interlayer dielectric film, a passivation film (not shown) is provided thereon. In the above mentioned steps, semiconductor memory device 1 has been fabricated.

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

In view of the similarity between the reference device 1 described above and the embodiments, the portions of the embodiments that are identical to the portions of reference device 1 will be given the same reference numerals as the portions of reference device 1. Moreover, a description of the fabrication process of the embodiments may be omitted for the sake of brevity, as the fabrication process of each embodiment is identical to that of reference device 1.

### First Embodiment

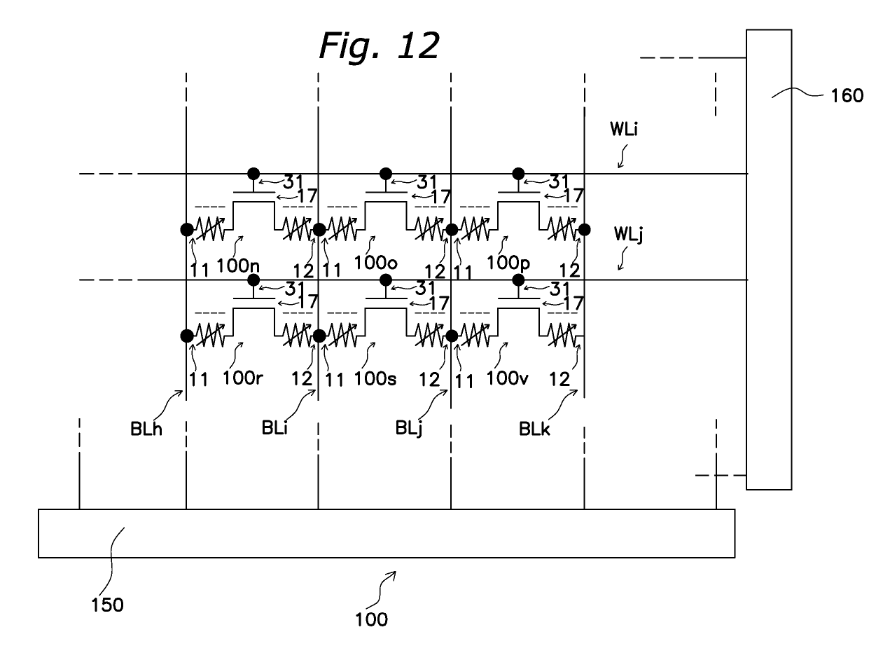

FIG. 12 is a circuit diagram of a semiconductor memory device in accordance with a first embodiment of the present invention. As shown in FIG. 12, a semiconductor memory device 100 is mainly comprised of a plurality of memory cells 100n, 100o, 100p, . . . , 100r, 100s, 100v, . . . , a first voltage applying section 160, and a second voltage applying section 150.

Memory cells 100n, . . . differ from Memory cells 1n, . . . of reference semiconductor memory device 1 in the functions of the first multilayer 141 and second multilayer 145.

First voltage applying section 160 is connected to gate electrodes 31 of memory cells 100n, 100o, 100p, . . . by way of word lines WLi, WLj . . . , thereby applying gates voltages VWi100, VWj100, . . . to gate electrodes 31 of memory cells 100n, 100o, 100p, . . . .

Second voltage applying section 150 is connected to first diffused region 11 and second diffused region 12 of memory cells 100n, 100o, 100p, . . . by way of bit lines BLh, BLi, BLj, BLk, . . . , thereby applying source voltages VBh100, . . . to one of the first diffused region 11 and second diffused region 12, and applying drain voltages VBi100, . . . to the other.

Operations of semiconductor memory device 100 will now be roughly described. Memory cells 100n, 100o, 100p, . . . receive gate voltages VWi100, VWj100, . . . from first voltage applying section 160 by way of word lines WLi, WLj . . . . When gate voltages VWi100, VWj100, . . . are H-level, channel forming regions 17 of corresponding memory cells 100n, 100o, 100p, . . . are placed in an ON-state, which enables current to flow between first diffused region 11 and second diffused region 12. When gate voltages VWi100, VWj100, . . . are L-level, channel forming regions 17 of corresponding memory cells 100n, 100o, 100p, . . . are placed in an OFF-state, which enables little or no current to flow between first diffused region 11 and second diffused region 12.

Meanwhile, memory cells 100n, 100o, 100p, . . . receive source voltages VBh100, . . . and drain voltages VBi100, . . . from second voltage applying section 150 by way of bit lines BLh, BLi, BLj, BLk, . . . .

A situation will now be considered in which source voltages VBh100, . . . are applied to first diffused regions 11 of memory cells 100n, 100o, 100p, . . . by way of bit lines BLh, . . . , and drain voltages VBi100, . . . are applied to second diffused region 12 of memory cells 100n, 100o, 100p, . . . by way of bit lines BLi, . . . . In this situation, when source voltages VBh100, . . . are higher than drain voltages VBi100, . . . , drain current Ids flows from first diffused region 11 to second diffused region 12 in memory cells where the applied gate voltage is H-level and where channel forming region 17 is in an ON-state. When source voltages VBh100, . . . are lower than drain voltages VBi100, . . . , drain current Ids flows from second diffused region 12 to first diffused region 11 in memory cells where the applied gate voltage is H-level and where channel forming region 17 is in an ON-state. In this way, an erasing operation, a programming operation and a reading operation are performed for selected memory cells through word lines WLi, . . . and bit lines BLh, . . . by first voltage applying section 160 and second voltage applying section 150. Operations may be explained similarly in a situation in which drain voltages VBh100, . . . are applied to first diffused regions 11 of memory cells 100n, 100o, 100p, . . . by way of bit lines BLh, . . . , and source voltages VBi100, . . . are applied to second diffused regions 12 of memory cells 100n, 100o, 100p, . . . by way of bit lines BLi, . . . .

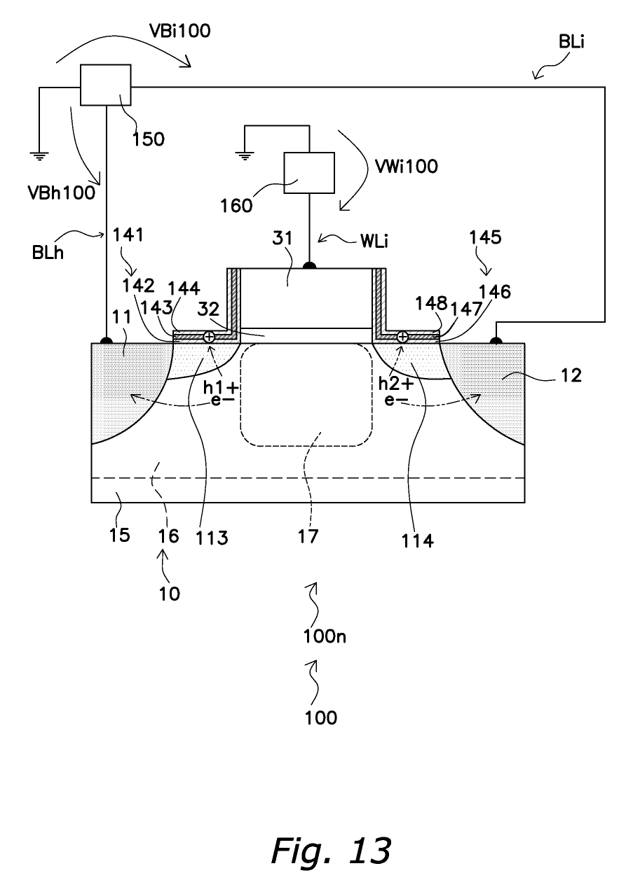

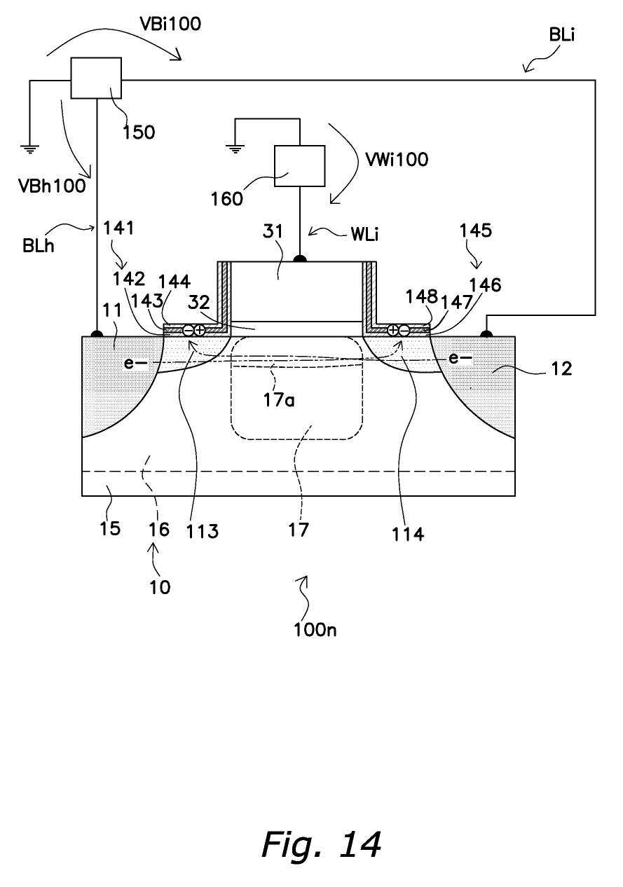

A memory cell in semiconductor memory device 100 will now be described in detail with reference to FIG. 13 and FIG. 14. FIG. 13 and FIG. 14 are cross-sectional views of the structure of a memory cell.

Referring to FIG. 13, memory cell 100n, as an example, is different from memory cell 1n in having first multilayer 141 instead of first multilayer 41, and second multilayer 145 instead of second multilayer 45.

First diffused region 11 receives either source voltage VBh100 or drain voltage VBh100. Gate electrode 31 receives gate voltage VWi100.

First multilayer 141 overlies semiconductor substrate 10 between first diffused region 11 and gate dielectric 32. First multilayer 141 is mainly comprised of first dielectric layer 142, charge accumulation layer 143, and second dielectric layer 144. First dielectric layer 142 insulates charge accumulation layer 143 from semiconductor substrate 10. Charge accumulation layer 143 accumulates a charge as a hole or an electron. Second dielectric layer 144 insulates charge accumulation layer 143 from its upper film. Namely, charge accumulation layer 143 is sandwiched between first dielectric layer 142 and second dielectric layer 144 so as to retain a charge as a hole or an electron in a stable manner. First dielectric layer 142 and second dielectric layer 144 are made of silicon dioxide as a main component, while charge accumulation layer 143 is made of silicon nitride as a main component.

Second diffused region 12 receives either source voltage VBi100 or drain voltage VBi100.

Second multilayer 145 overlies semiconductor substrate 10 between second diffused region 12 and gate dielectric 32. Second multilayer 145 is mainly comprised of first dielectric layer 146, charge accumulation layer 147, and second dielectric layer 148. First dielectric layer 146 insulates charge accumulation layer 147 from semiconductor substrate 10. Charge accumulation layer 147 accumulates a charge as a hole or an electron. Second dielectric layer 148 insulates charge accumulation layer 147 from its upper film. Namely, charge accumulation layer 147 is sandwiched between first dielectric layer 146 and second dielectric layer 148 so as to retain a charge as a hole or an electron in a stable manner. First dielectric layer 146 and second dielectric layer 148 are made of silicon dioxide as a main component, while charge accumulation layer 147 is made of silicon nitride as a main component.

The structure of memory cell 100n was described above as an example. The structures of other memory cells 100o, 100p, . . . are identical to that of memory cell 100n.

Operations of memory cell 100n, as an example, will now be described with reference to TABLE 2 below. Operations of other memory cells 100o, 100p, . . . are identical to those of memory cell 100n. FIG. 13 illustrates an erasing operation, while FIG. 14 illustrates a programming operation.

TABLE 2

| | Drain voltage | Gate voltage | Source voltage |
|---|---|---|---|
| Erase | +Vde100 | −Vge100 | Open |
| Program | +Vdw100 | +Vgw100 | 0 |
| Read | 0 | +Vgr100 | +Vsr100 |

First, an erasing operation will be described. In an erasing operation of first multilayer 141, gate voltage VWi100=−Vge100 (−6V, for example) is applied to gate electrode 31 by way of word line WLi. Drain voltage VBh100=+Vde100 (5V, for example) is applied to first diffused region 11, while second diffused region 12 (source voltage VBi100) is set open. Then, a high electric field is generated between gate electrode 31 and a drain electrode (first diffused region 11), and accordingly, an inter-band tunneling current is generated in response to a large change in the energy band at the edge of the drain electrode (first diffused region 11). The inter-band tunneling current flows through P-well region 16, directed to back gate 15 which is grounded, and generates hot-holes. As shown in FIG. 13, the hot-holes (h1+) are greatly attracted by gate voltage VWi100=−Vge100, and injected to charge accumulation layer 143 of first multilayer 141 at an amount that is greater than a neutralization amount. The neutralization amount is the amount of charge needed for neutralizing accumulated electrons. As a result, after being partially offset with electrons accumulated in charge accumulation layer 143, the injected hot-holes still reside in charge accumulation layer 143. Namely, positive charges accumulate in charge accumulation layer 143. Accordingly, data “1” previously programmed (written) in charge accumulation layer 143 of first multilayer 141 will be erased.

In an erasing operation of second multilayer 145, gate voltage VWi100=−Vge100 (−6V, for example) is applied to gate electrode 31 by way of word line WLi. First diffused region 11 (source voltage VBh100) is set open, while drain voltage VBi100=+Vde100 (5V, for example) is applied to second diffused region 12. Then, a high electric field is generated between gate electrode 31 and a drain electrode (second diffused region 12), and accordingly, an inter-band tunneling current is generated in response to the large change in the energy band at the edge of the drain electrode (second diffused region 12). The inter-band tunneling current flows through P-well region 16, directed to back gate 15 which is grounded, and generates hot-holes. As shown in FIG. 13, the hot-holes (h2+) are greatly attracted by gate voltage VWi100=−Vge100, and injected to charge accumulation layer 147 of second multilayer 145 at an amount that is greater than a neutralization amount. The neutralization amount is the amount of charge needed for neutralizing accumulated electrons. As a result, after being partially offset with electrons accumulated in charge accumulation layer 147, the injected hot-holes still reside in charge accumulation layer 147. Namely, positive charges will accumulate in charge accumulation layer 147. Accordingly, data “1” previously programmed (written) in charge accumulation layer 147 of second multilayer 145 will be erased.

A situation is described in the above erasing operation in which electrons are accumulated after performing programming for first multilayer 141 and second multilayer 145. However, it is appreciated by those skilled in the art that an erasing operation may be similarly performed when electrons are not accumulated (not programmed). Even in this situation, in the erasing operation, the injected hot-holes reside in first multilayer 141 and second multilayer 145, and positive charges will accumulate therein.

Secondly, a programming operation will be described. In a programming operation of first multilayer 141, gate voltage VWi100=+Vgw100 (8V, for example) is applied to gate electrode 31 by way of word line WLi. Drain voltage VBh100=+Vdw100 (5.5V, for example) is applied to first diffused region 11, while source voltage VBi100=0 is applied to second diffused region 12. Then, hot electrons are generated in such a way that electrons directed from a source electrode (second diffused region 12) to a drain electrode (first diffused region 11) are accelerated in a resistor changing region (third diffused region 113) adjacent to the drain electrode. The hot electrons are attracted by gate voltage VWi100=+Vgw100, and injected into charge accumulation layer 143 of first multilayer 141. Now that positive charges (holes) are accumulated in charge accumulation layer 143 of first multilayer 141, hot electron are injected more easily in order to charge accumulation layer 143 than to charge accumulation layer 43 (see FIG. 3). Therefore, data “1” is effectively programmed in charge accumulation layer 143 of first multilayer 141. Meanwhile, where gate voltage VWi100=0, hot electrons are not injected into charge accumulation layer 143 of first multilayer 141, and thus, data “1” is not programmed (data “0” is programmed) in charge accumulation layer 143 of first multilayer 141.

In a programming operation of second multilayer 145, gate voltage VWi100=+Vgw100 (8V, for example) is applied to gate electrode 31 by way of word line WLi. Source voltage VBh100=0 is applied to first diffused region 11, while drain voltage VBi100=+Vdw100 (5.5V, for example) is applied to second diffused region 12. Then, hot electrons are generated in such a way that electrons directed from a source electrode (first diffused region 11) to a drain electrode (second diffused region 12) are accelerated in a resistor changing region (fourth diffused region 114) adjacent to the drain electrode. The hot electrons are attracted by gate voltage VWi100=+Vgw100, and injected into charge accumulation layer 147 of second multilayer 145. Now that positive charges (holes) are accumulated in charge accumulation layer 147 of second multilayer 145, hot electrons are injected more easily in order to charge accumulation layer 147 than to charge accumulation layer 47 (see FIG. 3). Therefore, data “1” is effectively programmed in charge accumulation layer 147 of second multilayer 145. Meanwhile, where gate voltage VWi100=0, hot electrons are not injected into charge accumulation layer 147 of second multilayer 145, and thus, data “1” is not programmed (data “0” is programmed) in charge accumulation layer 147 of second multilayer 145.

The relationship between an erasing operation and a programming operation will now be described. In an erasing operation of first multilayer 141, positive charges (hot-holes) are mainly accumulated in first multilayer 141. In a programming operation of first multilayer 141, hot electrons are injected to first multilayer 141 in order to program after the erasing operation.

Namely, when data “1” is programmed in charge accumulation layer 143 of first multilayer 141, it is hard for current (electrons) to flow through third diffused region 113 due to negative charges (electrons) in charge accumulation layer 143, and the resistance of third diffused region 113 is high. Thus, as shown in FIG. 15, read current Ids is I101 (5 μA, for example) when the programming time is T1 (10 μs, for example). On the other hand, the current when data “1” is not programmed (data “0” is programmed) in charge accumulation layer 143 of first multilayer 141 flows even more easily through third diffused region 113 than the current when data “1” is not programmed (data “0” is programmed) in charge accumulation layer 43 of first multilayer 41 (see FIG. 4), and the resistance of third diffused region 113 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for first multilayer 141, and current Ids=I101 (5 μA, for example) when a programming operation is performed for first multilayer 141, will be large. The difference ΔIds100 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

In an erasing operation of second multilayer 145, positive charges (hot-holes) are mainly accumulated in second multilayer 145. In a programming operation of second multilayer 145, hot electrons are injected to second multilayer 145 in order to program after the erasing operation.

Namely, when data “1” is programmed in charge accumulation layer 147 of second multilayer 145, it is hard for current (electrons) to flow through fourth diffused region 114 due to negative charges (electrons) in charge accumulation layer 147, and the resistance of fourth diffused region 114 is high. Thus, as shown in FIG. 15, read current Ids is I101 (5 μA, for example) when programming time is T1 (10 μs, for example). On the other hand, the current when data “1” is not programmed (data “0” is programmed) in charge accumulation layer 147 of second multilayer 145 flows even more easily through fourth diffused region 114 than the current when data “1” is not programmed (data “0” is programmed) in charge accumulation layer 47 of second multilayer 45 (see FIG. 4), and the resistance of fourth diffused region 114 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for second multilayer 145, and current Ids=I101 (5 μA, for example) when a programming operation is performed for second multilayer 145, will be large. The difference ΔIds100 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

Modifications of the first embodiment will now be described.

(A) In an erasing operation, second voltage applying section 150 may provide a source electrode (second diffused region 12) with zero voltage as source voltages VBi100, instead of setting the source electrode open.

(B) In the above first embodiment, a condition under which negative charges (electrons) reside in first multilayer 141, for example, indicates that data “1” is programmed. However, it is appreciated by those skilled in the art that a condition under which negative charges (electrons) reside in first multilayer 141 and second multilayer 145 may indicate that data “0” is programmed.

(C) When the dopant concentration of third diffused region 113 is lower than that of first diffused region 11, third diffused region 113 may be P-type instead of N-type. Similarly, when the dopant concentration of fourth diffused region 114 is lower than that of second diffused region 12, fourth diffused region 114 may be P-type instead of N-type.

(D) In an erasing operation of first multilayer 141, hot-holes are injected in order to charge accumulation layer 143 at an amount greater than a neutralization amount. This injection is not necessarily performed at one time, and a plurality of injections may be possible. For example, after hot-holes are injected at a certain neutralization amount to offset, further injections may be performed.

### Second Embodiment

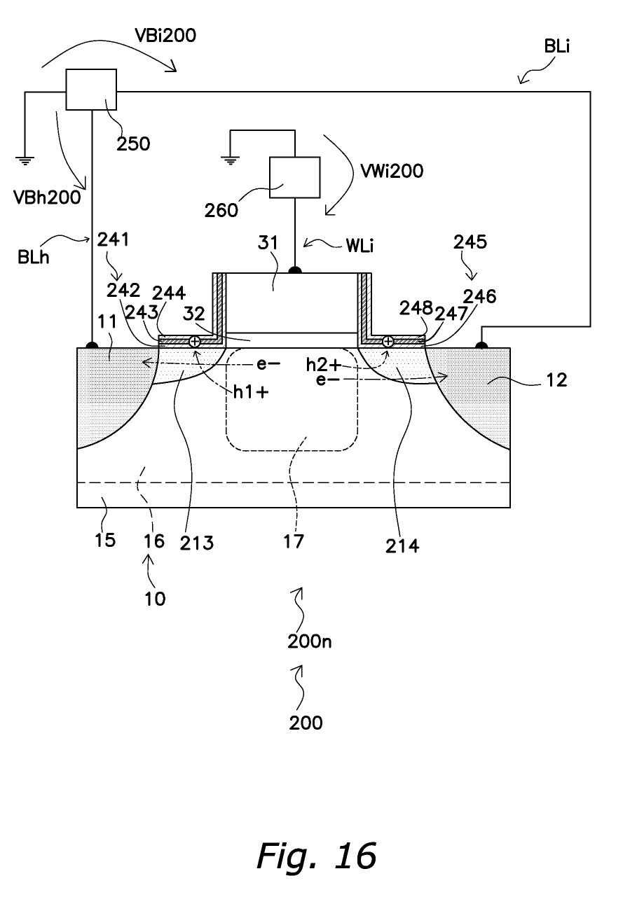

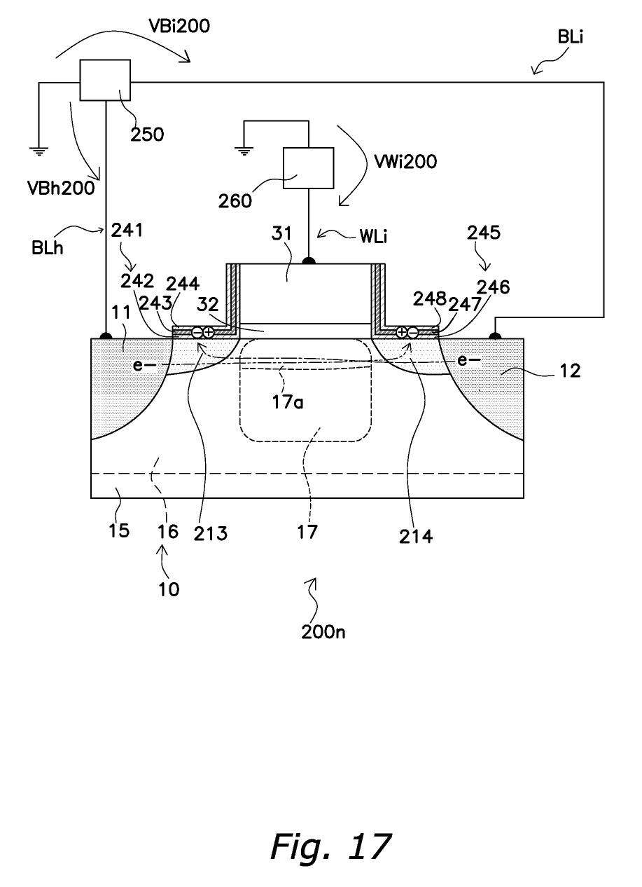

Referring now to FIG. 16 and FIG. 17, a semiconductor memory device according to a second embodiment will now be explained.

Similarly with the first embodiment, a semiconductor memory device 200 according to a second embodiment is comprised of memory cells 200n, 200o, 200p, . . . , 200r, 200s, 200v, . . . , arranged in a matrix (not shown), a first voltage applying section 260, and a second voltage applying section 250.

FIG. 16 and FIG. 17 are cross-sectional views of one memory cells 200n in semiconductor memory device 200 in accordance with second embodiment.

Memory cells 200n, . . . is different from memory cells 1n, . . . of reference semiconductor memory device 1 in the functions of a first multilayer 241 and a second multilayer 245.

First voltage applying section 260 is connected to gate electrodes 31 of memory cells 200n, 200o, 200p, . . . by way of word lines WLi, WLj . . . , thereby applying gates voltages VWi200, VWj200, . . . to gate electrodes 31 of memory cells 200n, 200o, 200p, . . . .

Second voltage applying section 250 is connected to first diffused region 11 and second diffused region 12 of memory cells 200n, 200o, 200p, . . . by way of bit lines BLh, BLi, BLj, BLk, . . . , thereby applying source voltages VBh200, to one of the first diffused region 11 and second diffused region 12, and applying drain voltages VBi200, . . . to the other.

Operations of semiconductor memory device 200 will now be roughly described. Memory cells 200n, 200o, 200p, . . . receive gate voltages VWi200, VWj200, . . . from first voltage applying section 260 by way of word lines WLi, WLj . . . . When gate voltages VWi200, VWj200, . . . are H-level, channel forming regions 17 of corresponding memory cells 200n, 200o, 200p, . . . are placed in an ON-state, which enables current to flow between first diffused region 11 and second diffused region 12. When gate voltages VWi200, VWj200, . . . are L-level, channel forming regions 17 of corresponding memory cells 200n, 200o, 200p, . . . are placed in an OFF-state, which enables little or no current to flow between first diffused region 11 and second diffused region 12.

Meanwhile, memory cells 200n, 200o, 200p, . . . receive source voltages VBh200, . . . and drain voltages VBi200, . . . from second voltage applying section 250 by way of bit lines BLh, BLi, BLj, BLk, . . . .

A situation will now considered in which source voltages VBh200, . . . are applied to first diffused regions 11 of memory cells 200n, 200o, 200p, . . . by way of bit lines BLh, . . . , and drain voltages VBi200, . . . are applied to second diffused region 12 of memory cells 200n, 200o, 200p, . . . by way of bit lines BLi, . . . . In this situation, when source voltages VBh200, . . . are higher than drain voltages VBi200, . . . , drain current Ids flows from first diffused region 11 to second diffused region 12 in memory cells where applied gate voltage is H-level and when channel forming region 17 is in an ON-state. When source voltages VBh200, . . . are lower than drain voltages VBi200, . . . , drain current Ids flows from second diffused region 12 to first diffused region 11 in memory cells where the applied gate voltage is H-level and where channel forming region 17 is in an ON-state. In this way, an erasing operation, a programming operation and a reading operation are performed for selected memory cells through word lines WLi, . . . and bit lines BLh, . . . by first voltage applying section 260 and second voltage applying section 250. Operations may be explained similarly in a situation in which drain voltages VBh200, . . . are applied to first diffused regions 11 of memory cells 200n, 200o, 200p, . . . by way of bit lines BLh, . . . , and source voltages VBi200, . . . are applied to second diffused regions 12 of memory cells 200n, 200o, 200p, . . . by way of bit lines BLi,

A memory cell in semiconductor memory device 200 will now be described in detail with reference to FIG. 16.

Referring to FIG. 16, memory cell 200n, as an example, is different from memory cell 1n in having first multilayer 241 instead of first multilayer 41, and second multilayer 245 instead of second multilayer 45.

First diffused region 11 receives either source voltage VBh200 or drain voltage VBh200. Gate electrode 31 receives gate voltage VWi200.

First multilayer 241 overlies semiconductor substrate 10 between first diffused region 11 and gate dielectric 32. First multilayer 241 is mainly comprised of first dielectric layer 242, charge accumulation layer 243, and second dielectric layer 244. First dielectric layer 242 insulates charge accumulation layer 243 from semiconductor substrate 10. Charge accumulation layer 243 accumulates a charge as a hole or an electron. Second dielectric layer 244 insulates charge accumulation layer 243 from its upper film. Namely, charge accumulation layer 243 is sandwiched between first dielectric layer 242 and second dielectric layer 244 so as to retain a charge as a hole or an electron in a stable manner. First dielectric layer 242 and second dielectric layer 244 are made of silicon dioxide as a main component, while charge accumulation layer 243 is made of silicon nitride as a main component.

Second diffused region 12 receives either source voltage VBi200 or drain voltage VBi200.

Second multilayer 245 overlies semiconductor substrate 10 between second diffused region 12 and gate dielectric 32. Second multilayer 245 is mainly comprised of first dielectric layer 246, charge accumulation layer 247, and second dielectric layer 248. First dielectric layer 246 insulates charge accumulation layer 247 from semiconductor substrate 10. Charge accumulation layer 247 accumulates a charge as a hole or an electron. Second dielectric layer 248 insulates charge accumulation layer 247 from its upper film. Namely, charge accumulation layer 247 is sandwiched between first dielectric layer 246 and second dielectric layer 248 so as to retain a charge as a hole or an electron in a stable manner. First dielectric layer 246 and second dielectric layer 248 are made of silicon dioxide as a main component, while charge accumulation layer 247 is made of silicon nitride as a main component.

The structure of memory cell 200n was described above as an example. The structures of the other memory cells 200o, 200p, . . . are identical to that of memory cell 200n.

Operations of memory cell 200n, as an example, will now be described with reference to TABLE 3 below. Operations of other memory cells 200o, 200p, . . . are identical to those of memory cell 200n. FIG. 16 illustrates an erasing operation, while FIG. 17 illustrates a programming operation.

TABLE 3

| | Drain voltage | Gate voltage | Source voltage |
|---|---|---|---|
| Erase | +Vde200 | +Vge200 | 0 |
| Program | +Vdw200 | +Vgw200 | 0 |
| Read | 0 | +Vgr200 | +Vsr200 |

First, an erasing operation will be described. In an erasing operation of first multilayer 241, gate voltage VWi200=+Vge200 (1V, for example) is applied to gate electrode 31 by way of word line WLi. Source voltage VBh200=0V (zero voltage) is applied to first diffused region 11, while drain voltage VBi200=+Vde200 (5V, for example) is applied to second diffused region 12. Then, a channel is formed in portion 17a (see FIG. 17) of channel forming region 17 that is adjacent to gate electrode 31. Electrons directed from a source electrode (first diffused region 11) to a drain electrode (second diffused region 12) generates hot-holes at that channel. As shown in FIG. 16, the hot-holes (h1+) are more greatly attracted by an electric field between the source electrode and the drain electrode than attracted by gate voltage VWi1=−Vge1 of reference device 1 (see FIG. 3), and then injected to charge accumulation layer 243 of first multilayer 241 at an amount greater than a neutralization amount. The neutralization amount is the amount of charge needed for neutralizing accumulated electrons. As a result, after being partially offset with electrons accumulated in charge accumulation layer 243, the injected hot-holes still reside in charge accumulation layer 243. Namely, positive charges will accumulate in charge accumulation layer 243. Accordingly, data “1” previously programmed (written) in charge accumulation layer 243 of first multilayer 241 will be erased.

In an erasing operation of second multilayer 245, gate voltage VWi200=+Vge200 (1V, for example) is applied to gate electrode 31 by way of word line WLi. Drain voltage VBh200=+Vde200 (5V, for example) is applied to first diffused region 11, while source voltage VBi200=0V (zero voltage) is applied to second diffused region 12. Then, a channel is formed in portion 17a (see FIG. 17) of channel forming region 17 that is adjacent to gate electrode 31. Electrons directed from a source electrode (second diffused region 12) to a drain electrode (first diffused region 11) generates hot-holes at that channel. As shown in FIG. 16, the hot-holes (h2+) are more greatly attracted by an electric field between the source electrode and the drain electrode than attracted by gate voltage VWi1=−Vge1 of reference device 1 (see FIG. 3), and then injected to charge accumulation layer 247 of second multilayer 245 at an amount greater than a neutralization amount. The neutralization amount is the amount of charge needed for neutralizing accumulated electrons. As a result, after being partially offset with electrons accumulated in charge accumulation layer 247, the injected hot-holes still reside in charge accumulation layer 247. Namely, positive charges will accumulate in charge accumulation layer 247. Accordingly, data “1” previously programmed (written) in charge accumulation layer 247 of second multilayer 245 will be erased.

A situation is described in the above erasing operation in which electrons are accumulated after performing programming for first multilayer 241 and second multilayer 245. However, it is appreciated by those skilled in the art that an erasing operation may be similarly performed when electrons are not accumulated (not programmed). Even in such a situation, in the erasing operation, the injected hot-holes reside in first multilayer 241 and second multilayer 245, and positive charges will accumulate therein.

Secondly, a programming operation will be described. In a programming operation of first multilayer 241, gate voltage VWi200=+Vgw200 (8V, for example) is applied to gate electrode 31 by way of word line WLi. Source voltage VBh200=0 is applied to first diffused region 11, while drain voltage VBi200=+Vdw200 (5.5V, for example) is applied to second diffused region 12. Then, hot electrons are generated in such a way that electrons directed from a source electrode (first diffused region 11) to a drain electrode (second diffused region 12) are accelerated in a resistor changing region (fourth diffused region 214) adjacent to the drain electrode. The hot electrons are attracted by gate voltage VWi200=+Vgw200, and injected into charge accumulation layer 243 of first multilayer 241. Now that positive charges (holes) are accumulated in charge accumulation layer 243 of first multilayer 241, hot electrons are injected more easily in order to charge accumulation layer 243 than to charge accumulation layer 43 of reference device 1 (see FIG. 3). Therefore, data “1” is effectively programmed in charge accumulation layer 243 of first multilayer 241. Meanwhile, where gate voltage VWi200=0, hot electrons are not injected into charge accumulation layer 243 of first multilayer 241, and thus, data “1” is not programmed (data “0” is programmed) in charge accumulation layer 243 of first multilayer 241.

In a programming operation of second multilayer 245, gate voltage VWi200=+Vgw200 (8V, for example) is applied to gate electrode 31 by way of word line WLi. Drain voltage VBh200=+Vdw200 (5.5V, for example) is applied to first diffused region 11, while source voltage VBi200=0 is applied to second diffused region 12. Then, hot electrons are generated in such a way that electrons directed from a source electrode (second diffused region 12) to a drain electrode (first diffused region 11) are accelerated in a resistor changing region (third diffused region 213) adjacent to the drain electrode. The hot electrons are attracted by gate voltage VWi200=+Vgw200, and injected into charge accumulation layer 247 of second multilayer 245. Now that positive charges (holes) are accumulated in charge accumulation layer 247 of second multilayer 245, hot electrons are injected more easily in order to charge accumulation layer 247 than to charge accumulation layer 47 of reference device 1 (see FIG. 3). Therefore, data “1” is effectively programmed in charge accumulation layer 247 of second multilayer 245. Meanwhile, where gate voltage VWi200=0, hot electrons are not injected into charge accumulation layer 247 of second multilayer 245, and thus, data “1” is not programmed (data “0” is programmed) in charge accumulation layer 247 of second multilayer 245.

The relationship between an erasing operation and a programming operation will now be described. In an erasing operation of first multilayer 241, positive charges (hot-holes) are mainly accumulated in first multilayer 241. In a programming operation of first multilayer 241, hot electrons are injected to first multilayer 241 in order to program after the erasing operation.

Namely, when data “1” is programmed in charge accumulation layer 243 of first multilayer 241, it is hard for current (electrons) to flow through third diffused region 213 due to negative charges (electrons) in charge accumulation layer 243, and the resistance of third diffused region 213 is high. Thus, as shown in FIG. 15, read current Ids is I101 (5 μA, for example) when the programming time is T1 (10 μs, for example). On the other hand, the current when data “1” is not programmed (data “0” is programmed) in charge accumulation layer 247 of second multilayer 245 flows even more easily, due to positive charges (holes) in charge accumulation layer 243, through third diffused region 213 than the current when data “1” is not programmed (data “0” is programmed) in charge accumulation layer 47 of second multilayer 45 (see FIG. 4), and accordingly, the resistance of third diffused region 213 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for first multilayer 241, and current Ids=I101 (5 μA, for example) when a programming operation is performed for first multilayer 241, will be large. The difference ΔIds200 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

In an erasing operation of second multilayer 245, positive charges (hot-holes) are mainly accumulated in second multilayer 245. In a programming operation of second multilayer 245, hot electrons are injected to second multilayer 245 in order to program after the erasing operation.

Namely, when data “1” is programmed in charge accumulation layer 247 of second multilayer 245, it is hard for current (electrons) to flow through fourth diffused region 214 due to negative charges (electrons) in charge accumulation layer 247, and the resistance of fourth diffused region 214 is high. Thus, as shown in FIG. 15, read current Ids is I101 (5 μA, for example) when the programming time is T1 (10 μs, for example). On the other hand, current when data “1” is not programmed (data “0” is programmed) in charge accumulation layer 247 of second multilayer 245 flows even more easily, due to positive charges (holes) in charge accumulation layer 245, through fourth diffused region 214 than current when data “1” is not programmed (data “0” is programmed) in charge accumulation layer 47 of second multilayer 45 (see FIG. 4), and accordingly, the resistance of fourth diffused region 214 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for second multilayer 245, and current Ids=I101 (5 μA, for example) when a programming operation is performed for second multilayer 245, will be large. The difference ΔIds100 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

### Third Embodiment

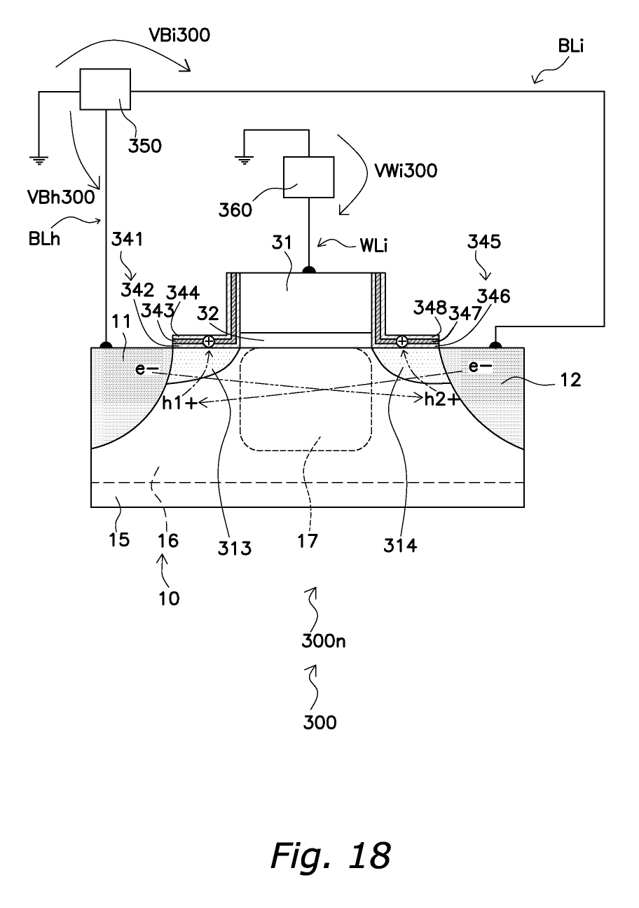

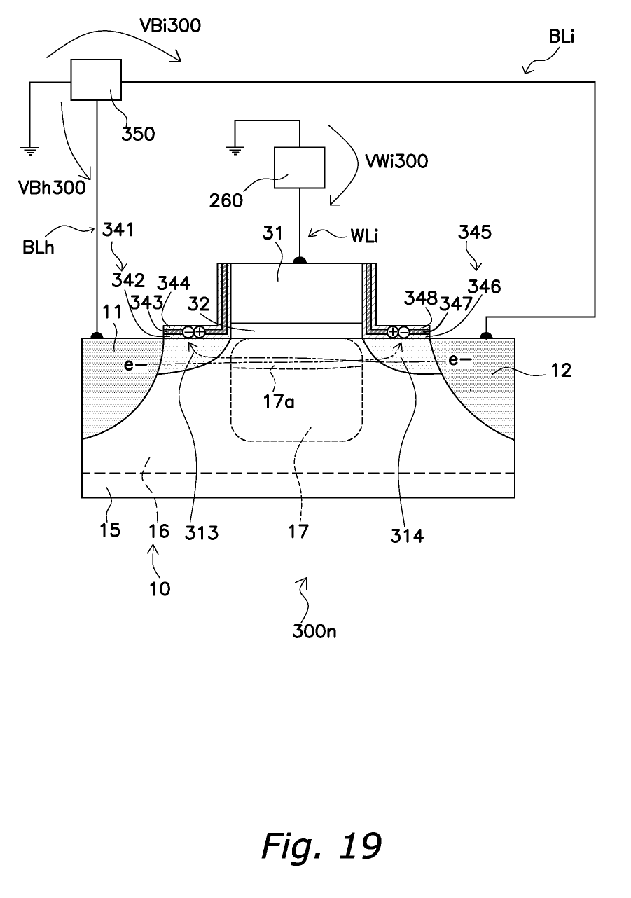

Referring now to FIG. 18 and FIG. 19, a semiconductor memory device according to a third embodiment will now be explained.

Similarly with the first embodiment, a semiconductor memory device 300 according to a third embodiment is comprised of memory cells 300n, 300o, 300p, . . . , 300r, 300s, 300v, . . . , arranged in a matrix (not shown), first voltage applying section 360, and second voltage applying section 350.

FIG. 18 and FIG. 19 are cross-sectional views of one memory cells 300n in semiconductor memory device 300 in accordance with the second embodiment.

Memory cells 300n, . . . is different from memory cells 1n, . . . of reference semiconductor memory device 1 in the functions of a first multilayer 341 and a second multilayer 345.

First voltage applying section 360 is connected to gate electrodes 31 of memory cells 300n, 300o, 300p, . . . by way of word lines WLi, WLj . . . , thereby applying gates voltages VWi300, VWj300, . . . to gate electrodes 31 of memory cells 300n, 300o, 300p, . . . .

Second voltage applying section 350 is connected to first diffused region 11 and second diffused region 12 of memory cells 300n, 300o, 300p, by way of bit lines BLh, BLi, BLj, BLk, . . . , thereby applying source voltages VBh300, to one of the first diffused region 11 and second diffused region 12, and applying drain voltages VBi300, . . . to the other.

Operations of semiconductor memory device 300 will now be roughly described. Memory cells 300n, 300o, 300p, . . . receive gate voltages VWi300, VWj300, . . . from first voltage applying section 360 by way of word lines WLi, WLj . . . . When gate voltages VWi300, VWj300, . . . are H-level, channel forming regions 17 of corresponding memory cells 300n, 300o, 300p, . . . are placed in an ON-state, which enables current to flow between first diffused region 11 and second diffused region 12. When gate voltages VWi300, VWj300, . . . are L-level, channel forming regions 17 of corresponding memory cells 300n, 300o, 300p, . . . are placed in an OFF-state, which enables little or no current to flow between first diffused region 11 and second diffused region 12.

Meanwhile, memory cells 300n, 300o, 300p, . . . receive source voltages VBh300, . . . and drain voltages VBi300, . . . from second voltage applying section 350 by way of bit lines BLh, BLi, BLj, BLk, . . . .

A situation will now considered in which source voltages VBh300, . . . are applied to first diffused regions 11 of memory cells 300n, 300o, 300p, . . . by way of bit lines BLh, . . . , and drain voltages VBi300, . . . are applied to second diffused region 12 of memory cells 300n, 300o, 300p, . . . by way of bit lines BLi, . . . . In this situation, when source voltages VBh300, . . . are higher than drain voltages VBi300, . . . , drain current Ids flows from first diffused region 11 to second diffused region 12 in memory cells where the applied gate voltage is H-level and where channel forming region 17 is in an ON-state. When source voltages VBh300, . . . are lower than drain voltages VBi300, . . . , drain current Ids flows from second diffused region 12 to first diffused region 11 in memory cells where the applied gate voltage is H-level and where channel forming region 17 is in an ON-state. In this way, an erasing operation, a programming operation and a reading operation are performed for selected memory cells through word lines WLi, . . . and bit lines BLh, . . . by first voltage applying section 360 and second voltage applying section 350.

Operations may be explained similarly in a situation in which drain voltages VBh300, . . . are applied to first diffused regions 11 of memory cells 300n, 300o, 300p, . . . by way of bit lines BLh, . . . , and source voltages VBi300, . . . are applied to second diffused regions 12 of memory cells 300n, 300o, 300p, . . . by way of bit lines BLi, . . . .

A memory cell in semiconductor memory device 300 will now be described in detail with reference to FIG. 18.

Referring to FIG. 18, memory cell 300n, as an example, is different from memory cell 1n in having first multilayer 341 instead of first multilayer 41, and second multilayer 345 instead of second multilayer 45.

First diffused region 11 receives either source voltage VBh300 or drain voltage VBh300. Gate electrode 31 receives gate voltage VWi300.

First multilayer 341 overlies semiconductor substrate 10 between first diffused region 11 and gate dielectric 32. First multilayer 341 is mainly comprised of first dielectric layer 342, charge accumulation layer 343, and second dielectric layer 344. First dielectric layer 342 insulates charge accumulation layer 343 from semiconductor substrate 10. Charge accumulation layer 343 accumulates a charge as a hole or an electron. Second dielectric layer 344 insulates charge accumulation layer 343 from its upper film. Namely, charge accumulation layer 343 is sandwiched between first dielectric layer 342 and second dielectric layer 344 so as to retain a charge as a hole or an electron in a stable manner. First dielectric layer 342 and second dielectric layer 344 are made of silicon dioxide as a main component, while charge accumulation layer 343 is made of silicon nitride as a main component.

Second diffused region 12 receives either source voltage VBi300 or drain voltage VBi300.

Second multilayer 345 overlies semiconductor substrate 10 between second diffused region 12 and gate dielectric 32. Second multilayer 345 is mainly comprised of first dielectric layer 346, charge accumulation layer 347, and second dielectric layer 348. First dielectric layer 346 insulates charge accumulation layer 347 from semiconductor substrate 10. Charge accumulation layer 347 accumulates a charge as a hole or an electron. Second dielectric layer 348 insulates charge accumulation layer 347 from its upper film. Namely, charge accumulation layer 347 is sandwiched between first dielectric layer 346 and second dielectric layer 348 so as to retain a charge as a hole or an electron in a stable manner. First dielectric layer 346 and second dielectric layer 348 are made of silicon dioxide as a main component, while charge accumulation layer 347 is made of silicon nitride as a main component.

The structure of memory cell 300n was described above as an example. The structures of other memory cells 300o, 300p, . . . are identical to that of memory cell 300n.

Operations of memory cell 300n, as an example, will now be described with reference to TABLE 4 below. Operations of other memory cells 300o, 300p, . . . are identical to those of memory cell 300n. FIG. 18 illustrates an erasing operation, while FIG. 19 illustrates a programming operation.

TABLE 4

| | Drain voltage | Gate voltage | Source voltage |
|---|---|---|---|
| Erase | +Vde300 | 0 | −Vse300 |
| Program | +Vdw300 | +Vgw300 | 0 |
| Read | 0 | +Vgr300 | +Vsr300 |

First, an erasing operation will be described. In an erasing operation of first multilayer 341, gate voltage VWi300=0 is applied to gate electrode 31 by way of word line WLi. Drain voltage VBh300=+Vde300 (5V, for example) is applied to first diffused region 11, while source voltage VBi300=−Vse300 is applied to second diffused region 12. Then, electrons are released from a source electrode (second diffused region 12) to P-well region 16. After reaching a depletion layer of the drain electrode (first diffused region 11), the electrons are accelerated by an electric field to generate hot-holes. The hot-holes (h1+) are more greatly attracted by an electric field between gate electrode 31 and the drain electrode than attracted by gate voltage VWi1=−Vge1 of reference device 1 (see FIG. 3), and then injected to charge accumulation layer 343 of first multilayer 341 at an amount greater than a neutralization amount. The neutralization amount is the amount of charge needed for neutralizing accumulated electrons. As a result, after being partially offset with electrons accumulated in charge accumulation layer 343, the injected hot-holes still reside in charge accumulation layer 343. Namely, positive charges will accumulate in charge accumulation layer 343. Accordingly, data “1” previously programmed (written) in charge accumulation layer 343 of first multilayer 341 will be erased.

In an erasing operation of second multilayer 345, gate voltage VWi300=0 is applied to gate electrode 31 by way of word line WLi. Source voltage VBh300=−Vse300 (−1V, for example) is applied to first diffused region 11, while drain voltage VBi300=+Vde300 (5V, for example) is applied to second diffused region 12. Then, electrons are released from a source electrode (first diffused region 11) to P-well region 16. After reaching a depletion layer of the drain electrode (second diffused region 12), the electrons are accelerated by an electric field to generate hot-holes. The hot-holes (h2+) are more greatly attracted due to an electric field between gate electrode 31 and the drain electrode than attracted by gate voltage VWi1=−Vge1 of reference device 1 (see FIG. 3), and then injected to charge accumulation layer 347 of second multilayer 345 at an amount greater than a neutralization amount. The neutralization amount is the amount of charge needed for neutralizing accumulated electrons. As a result, after being partially offset with electrons accumulated in charge accumulation layer 347, the injected hot-holes still reside in charge accumulation layer 347. Namely, positive charges will accumulate in charge accumulation layer 347. Accordingly, data “1” previously programmed (written) in charge accumulation layer 347 of second multilayer 345 will be erased.

A situation is described in the above erasing operation in which electrons are accumulated after performing programming for first multilayer 341 and second multilayer 345. However, it is appreciated by those skilled in the art that an erasing operation may be similarly performed when electrons are not accumulated (not programmed). Even in this situation, in the erasing operation, the injected hot-holes reside in first multilayer 341 and second multilayer 345, and positive charges will accumulate therein.

Secondly, a programming operation will be described. In a programming operation of first multilayer 341, gate voltage VWi300=+Vgw300 (8V, for example) is applied to gate electrode 31 by way of word line WLi. Drain voltage VBh300=+Vdw300 (5.5V, for example) is applied to first diffused region 11, while source voltage VBi300=0 is applied to second diffused region 12. Then, hot electrons are generated in such a way that electrons directed from a source electrode (second diffused region 12) to a drain electrode (first diffused region 11) are accelerated in a resistor changing region (third diffused region 313) adjacent to the drain electrode. The hot electrons are attracted by gate voltage VWi300=+Vgw300, and injected into charge accumulation layer 343 of first multilayer 341. Now that positive charges (holes) are accumulated in charge accumulation layer 343 of first multilayer 341, hot electrons are injected more easily in order to charge accumulation layer 343 than to charge accumulation layer 43 of reference device 1 (see FIG. 3). Therefore, data “1” is effectively programmed in charge accumulation layer 343 of first multilayer 341. Meanwhile, where gate voltage VWi300=0, hot electrons are not injected into charge accumulation layer 343 of first multilayer 341, and thus, data “1” is not programmed (data “0” is programmed) in charge accumulation layer 343 of first multilayer 341.

In a programming operation of second multilayer 345, gate voltage VWi300=+Vgw300 (8V, for example) is applied to gate electrode 31 by way of word line WLi. Source voltage VBh300=0 is applied to first diffused region 11, while drain voltage VBi300=+Vdw300 (5.5V, for example) is applied to second diffused region 12. Then, hot electrons are generated in such a way that electrons directed from a source electrode (first diffused region 11) to a drain electrode (second diffused region 12) are accelerated in a resistor changing region (fourth diffused region 314) adjacent to the drain electrode. The hot electrons are attracted by gate voltage VWi300=+Vgw300, and injected into charge accumulation layer 347 of second multilayer 345. Now that positive charges (holes) are accumulated in charge accumulation layer 347 of second multilayer 345, hot electrons are injected more easily in order to charge accumulation layer 347 than to charge accumulation layer 47 of reference device 1 (see FIG. 3). Therefore, data “1” is effectively programmed in charge accumulation layer 347 of second multilayer 345. Meanwhile, where gate voltage VWi300=0, hot electrons are not injected into charge accumulation layer 347 of second multilayer 345, and thus, data “1” is not programmed (data “0” is programmed) in charge accumulation layer 347 of second multilayer 345.

The relationship between an erasing operation and a programming operation will now be described. In an erasing operation of first multilayer 341, positive charges (hot-holes) are mainly accumulated in first multilayer 341. In a programming operation of first multilayer 341, hot electrons are injected to first multilayer 341 in order to program after the erasing operation.

Namely, when data “1” is programmed in charge accumulation layer 343 of first multilayer 341, it is hard for current (electrons) to flow through third diffused region 313 due to negative charges (electrons) in charge accumulation layer 343, and the resistance of third diffused region 313 is high. Thus, as shown in FIG. 15, read current Ids is I101 (5 μA, for example) when the programming time is T1 (10 μs, for example). On the other hand, current when data “1” is not programmed (data “0” is programmed) in charge accumulation layer 343 of first multilayer 341 flows even more easily, due to positive charges (holes) in charge accumulation layer 343, through third diffused region 313 than current when data “1” is not programmed (data “0” is programmed) in charge accumulation layer 47 of second multilayer 45 (see FIG. 4), and accordingly, the resistance of third diffused region 313 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for first multilayer 341, and current Ids=I101 (5 μA, for example) when a programming operation is performed for first multilayer 341, will be large. The difference ΔIds100 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

In an erasing operation of second multilayer 345, positive charges (hot-holes) are mainly accumulated in second multilayer 345. In a programming operation of second multilayer 345, hot electrons are injected to second multilayer 345 in order to program after the erasing operation.

Namely, when data “1” is programmed in charge accumulation layer 347 of second multilayer 345, it is hard for current (electrons) to flow through fourth diffused region 314 due to negative charges (electrons) in charge accumulation layer 347, and the resistance of fourth diffused region 314 is high. Thus, as shown in FIG. 15, read current Ids is I101 (5 μA, for example) when the programming time is T1 (10 μs, for example). On the other hand, current when data “1” is not programmed (data “0” is programmed) in charge accumulation layer 347 of second multilayer 345 flows even more easily, due to positive charges (holes) in charge accumulation layer 347, through fourth diffused region 314 than current when data “1” is not programmed (data “0” is programmed) in charge accumulation layer 47 of second multilayer 45 (see FIG. 4), and accordingly, the resistance of fourth diffused region 314 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for second multilayer 345, and current Ids=I101 (5 μA, for example) when a programming operation is performed for second multilayer 345, will be large. The difference ΔIds100 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

### Fourth Embodiment

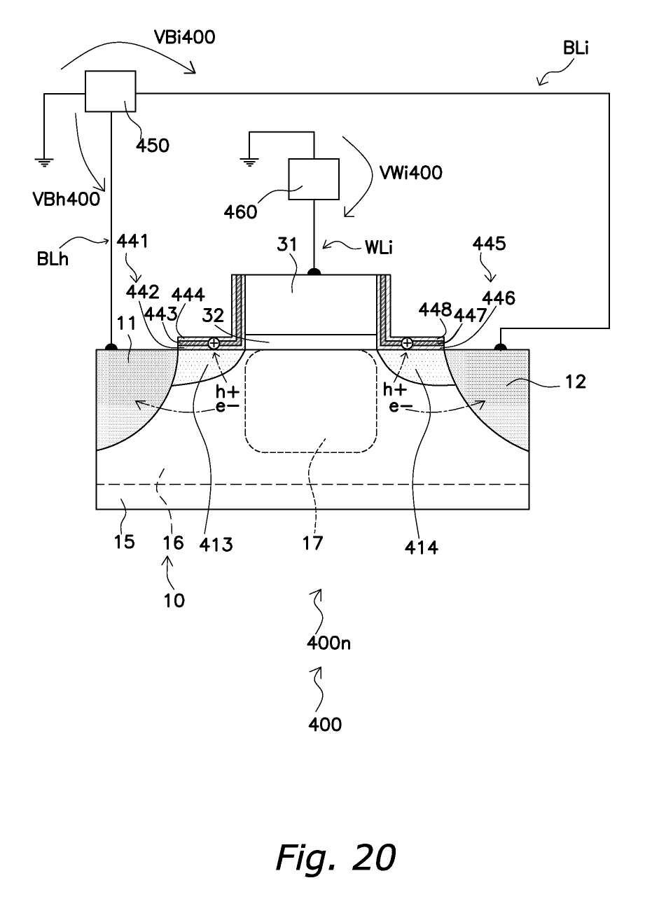

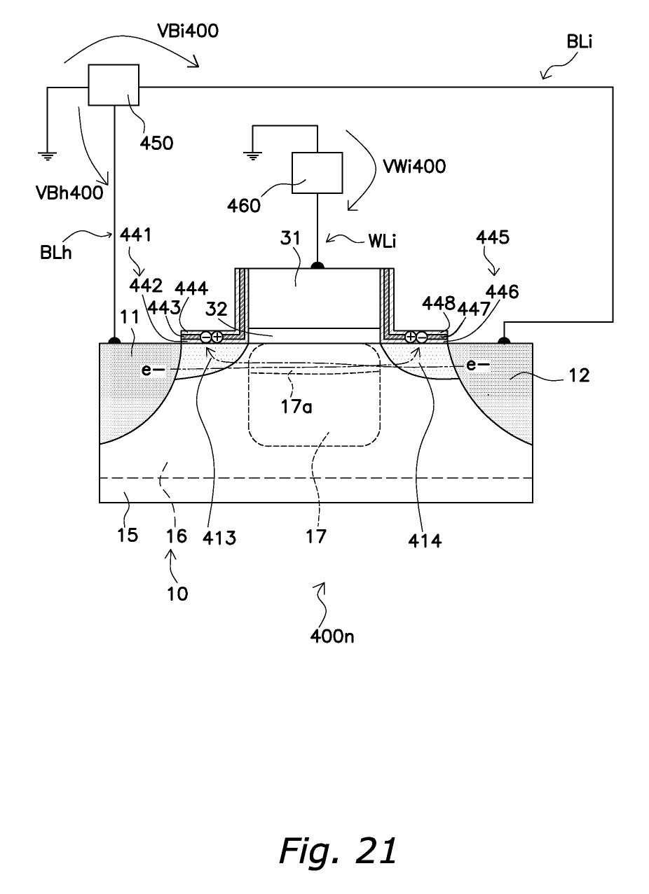

Referring now to FIG. 20 and FIG. 21, a semiconductor memory device according to a fourth embodiment will now be explained.

Similarly with the first embodiment, a semiconductor memory device 400 according to a fourth embodiment is comprised of memory cells 400n, 400o, 400p, . . . , 400r, 400s, 400v, . . . , arranged in a matrix (not shown), a first voltage applying section 460, and a second voltage applying section 450.

FIG. 20 and FIG. 21 are cross-sectional views of one memory cells 400n in semiconductor memory device 400 in accordance with the second embodiment.

Memory cells 400n, . . . is different from memory cells 1n, . . . of reference semiconductor memory device 1 in the functions of first multilayer 441 and second multilayer 445.

First voltage applying section 460 is connected to gate electrodes 31 of memory cells 400n, 400o, 400p, . . . by way of word lines WLi, WLj . . . , thereby applying gates voltages VWi400, VWj400, . . . to gate electrodes 31 of memory cells 400n, 400o, 400p, . . . . Gate voltages VWi400, VWj400, . . . are sufficiently large enough to turn channel forming region 17 ON or OFF.

Second voltage applying section 450 is connected to first diffused region 11 and second diffused region 12 of memory cells 400n, 400o, 400p, . . . by way of bit lines BLh, BLi, BLj, BLk, . . . , thereby applying source voltages VBh400, to one of the first diffused region 11 and second diffused region 12, and applying drain voltages VBi400, . . . to the other. Source voltages VBh400, . . . and drain voltages VBi400, . . . are sufficiently large enough to perform erasing, programming, and reading operations.

Operations of semiconductor memory device 400 will now be roughly described. Memory cells 400n, 400o, 400p, . . . receive gate voltages VWi400, VWj400, . . . from first voltage applying section 460 by way of word lines WLi, WLj . . . . When gate voltages VWi400, VWj400, . . . are H-level, channel forming regions 17 of corresponding memory cells 400n, 400o, 400p, . . . are placed in an ON-state, which enables current to flow between first diffused region 11 and second diffused region 12. When gate voltages VWi400, VWj400, . . . are L-level, channel forming regions 17 of corresponding memory cells 400n, 400o, 400p, . . . are placed in an OFF-state, which enables little or no current to flow between first diffused region 11 and second diffused region 12.

Meanwhile, memory cells 400n, 400o, 400p, . . . receive source voltages VBh400, . . . and drain voltages VBi400, . . . from second voltage applying section 450 by way of bit lines BLh, BLi, BLj, BLk, . . . .

A situation will now be considered in which source voltages VBh400, . . . are applied to first diffused regions 11 of memory cells 400n, 400o, 400p, . . . by way of bit lines BLh, . . . , and drain voltages VBi400, . . . are applied to second diffused region 12 of memory cells 400n, 400o, 400p, . . . by way of bit lines BLi, . . . . In this situation, when source voltages VBh400, . . . are higher than drain voltages VBi400, . . . , drain current Ids flows from first diffused region 11 to second diffused region 12 in memory cells where the applied gate voltage is H-level and where channel forming region 17 is in an ON-state. When source voltages VBh400, . . . are lower than drain voltages VBi400, . . . , drain current Ids flows from second diffused region 12 to first diffused region 11 in memory cells where the applied gate voltage is H-level and where channel forming region 17 is in an ON-state. In this way, an erasing operation, a programming operation and a reading operation are performed for selected memory cells through word lines WLi, . . . and bit lines BLh, . . . by first voltage applying section 460 and second voltage applying section 450.

Operations may be explained similarly in a situation in which drain voltages VBh400, . . . are applied to first diffused regions 11 of memory cells 400n, 400o, 400p, . . . by way of bit lines BLh, . . . , and source voltages VBi400, . . . are applied to second diffused regions 12 of memory cells 400n, 400o, 400p, . . . by way of bit lines BLi, . . . .

A memory cell in semiconductor memory device 400 will now be described in detail with reference to FIG. 20.

Referring to FIG. 20, memory cell 400n, as an example, is different from memory cell 1n in having first multilayer 441 instead of first multilayer 41, and second multilayer 445 instead of second multilayer 45.

First diffused region 11 receives either source voltage VBh400 or drain voltage VBh400. Gate electrode 31 receives gate voltage VWi400.

First multilayer 441 overlies semiconductor substrate 10 between first diffused region 11 and gate dielectric 32. First multilayer 441 is mainly comprised of first dielectric layer 442, charge accumulation layer 443, and second dielectric layer 444. First dielectric layer 442 insulates charge accumulation layer 443 from semiconductor substrate 10. Charge accumulation layer 443 accumulates a charge as a hole or an electron. Second dielectric layer 444 insulates charge accumulation layer 443 from its upper film. Namely, charge accumulation layer 443 is sandwiched between first dielectric layer 442 and second dielectric layer 444 so as to retain a charge as a hole or an electron in a stable manner. First dielectric layer 442 and second dielectric layer 444 are made of silicon dioxide as a main component, while charge accumulation layer 443 is made of silicon nitride as a main component.

Second diffused region 12 receives either source voltage VBi400 or drain voltage VBi400.

Second multilayer 445 overlies semiconductor substrate 10 between second diffused region 12 and gate dielectric 32. Second multilayer 445 is mainly comprised of first dielectric layer 446, charge accumulation layer 447, and second dielectric layer 448. First dielectric layer 446 insulates charge accumulation layer 447 from semiconductor substrate 10. Charge accumulation layer 447 accumulates a charge as a hole or an electron. Second dielectric layer 448 insulates charge accumulation layer 447 from its upper film. Namely, charge accumulation layer 447 is sandwiched between first dielectric layer 446 and second dielectric layer 448 so as to retain a charge as a hole or an electron in a stable manner. First dielectric layer 446 and second dielectric layer 448 are made of silicon dioxide as a main component, while charge accumulation layer 447 is made of silicon nitride as a main component.

The structure of memory cell 400n was described above as an example. The structures of other memory cells 400o, 400p, . . . are identical to that of memory cell 400n.

Operations of memory cell 400n, as an example, will now be described with reference to TABLE 5 below. Operations of other memory cells 400o, 400p, . . . are identical to those of memory cell 400n. FIG. 20 illustrates an erasing operation, while FIG. 21 illustrates a programming operation.

TABLE 5

| | Drain voltage | Gate voltage | Source voltage |
|---|---|---|---|
| Erase | +Vde400 | −Vge400 | +Vse400 |
| Program | +Vdw400 | +Vgw400 | 0 |
| Read | 0 | +Vgr400 | +Vsr400 |

First, an erasing operation will be described. An erasing operation of the present embodiment is characterized in that an erasing operation of first multilayer 441 and second multilayer 445 are performed simultaneously, as opposed to an erasing operation of reference device 1.

In an erasing operation of first multilayer 441 and second multilayer 445, gate voltage VWi400=−Vge400 (−6V, for example) is applied to gate electrode 31 by way of word line WLi. Drain voltage VBh400=+Vde400 (5V, for example) is applied to first diffused region 11, while source voltage VBi400=+Vse400 (5V, for example) is applied to second diffused region 12. Then, a high electric field is generated between gate electrode 31 and a drain electrode (first diffused region 11), and accordingly, an inter-band tunneling current is generated in response to the large change in the energy band at the edge of the drain electrode (first diffused region 11). A high electric field is also generated between gate electrode 31 and a source electrode (second diffused region 12), and accordingly, an inter-band tunneling current is generated in response to the large change in the energy band at the edge of the source electrode (second diffused region 12). The above two inter-band tunneling currents flow through P-well region 16, directed to back gate 15 which is grounded, and generates hot-holes. The hot-holes (h+) are more greatly attracted by gate voltage VWi400=−Vge400 than attracted by gate voltage VWi1=−Vge1 of reference device 1 (see FIG. 3), and then injected to both charge accumulation layer 443 of first multilayer 441 and charge accumulation layer 447 of second multilayer 445, at an amount greater than a neutralization amount. The neutralization amount is the amount of charge needed for neutralizing accumulated electrons. As a result, after being partially offset with electrons accumulated in charge accumulation layers 443, 447, the injected hot-holes still reside in charge accumulation layers 443, 447. Namely, positive charges will accumulate in charge accumulation layers 443, 447. Accordingly, data “1” previously programmed (written) in charge accumulation layer 443 of first multilayer 441 will be erased, while data “1” previously programmed (written) in charge accumulation layer 447 of second multilayer 445 will be erased.

A situation is described in the above erasing operation in which electrons are accumulated after performing programming for first multilayer 441 and second multilayer 445. However, it is appreciated by those skilled in the art that an erasing operation may be similarly performed when electrons are not accumulated (not programmed). Even in this situation, in the erasing operation, the injected hot-holes reside in first multilayer 441 and second multilayer 445, and positive charges will accumulate therein.

Secondly, a programming operation will be described. In a programming operation of first multilayer 441, gate voltage VWi400=+Vgw400 (8V, for example) is applied to gate electrode 31 by way of word line WLi. Drain voltage VBh400=+Vdw400 (5.5V, for example) is applied to first diffused region 11, while source voltage VBi400=0 is applied to second diffused region 12. Then, hot electrons are generated in such a way that electrons directed from a source electrode (second diffused region 12) to a drain electrode (first diffused region 11) are accelerated in a resistor changing region (third diffused region 413) adjacent to the drain electrode. The hot electrons are attracted by gate voltage VWi400=+Vgw400, and injected into charge accumulation layer 443 of first multilayer 441. Now that positive charges (holes) are accumulated in charge accumulation layer 443 of first multilayer 441, hot electrons are injected more easily in order to charge accumulation layer 443 than to charge accumulation layer 43 of reference device 1 (see FIG. 3). Therefore, data “1” is effectively programmed in charge accumulation layer 443 of first multilayer 441. Meanwhile, where gate voltage VWi400=0, hot electrons are not injected into charge accumulation layer 443 of first multilayer 441, and thus, data “1” is not programmed (data “0” is programmed) in charge accumulation layer 443 of first multilayer 441.

In a programming operation of second multilayer 445, gate voltage VWi400=+Vgw400 (8V, for example) is applied to gate electrode 31 by way of word line WLi. Source voltage VBh400=0 is applied to first diffused region 11, while drain voltage VBi400=+Vdw400 (5.5V, for example) is applied to second diffused region 12. Then, hot electrons are generated in such a way that electrons directed from a source electrode (first diffused region 11) to a drain electrode (second diffused region 12) are accelerated in a resistor changing region (fourth diffused region 414) adjacent to the drain electrode. The hot electrons are attracted by gate voltage VWi400=+Vgw400, and injected into charge accumulation layer 447 of second multilayer 445. Now that positive charges (holes) are accumulated in charge accumulation layer 447 of second multilayer 445, hot electrons are injected more easily in order to charge accumulation layer 447 than to charge accumulation layer 47 of reference device 1 (see FIG. 3). Therefore, data “1” is effectively programmed in charge accumulation layer 447 of second multilayer 445. Meanwhile, where gate voltage VWi400=0, hot electrons are not injected into charge accumulation layer 447 of second multilayer 445, and thus, data “1” is not programmed (data “0” is programmed) in charge accumulation layer 447 of second multilayer 445.

The relationship between an erasing operation and a programming operation will now be described. In an erasing operation of first multilayer 441, positive charges (hot-holes) are mainly accumulated in first multilayer 441. In a programming operation of first multilayer 441, hot electrons are injected to first multilayer 441 in order to program after the erasing operation.

Namely, when data “1” is programmed in charge accumulation layer 443 of first multilayer 441, it is hard for current (electrons) to flow through third diffused region 413 due to negative charges (electrons) in charge accumulation layer 443, and the resistance of third diffused region 413 is high. Thus, as shown in FIG. 15, read current Ids is I101 (5 μA, for example) when the programming time is T1 (10 μs, for example). On the other hand, current when data “1” is not programmed (data “0” is programmed) in charge accumulation layer 443 of first multilayer 441 flows even more easily, due to positive charges (holes) in charge accumulation layer 443, through third diffused region 413 than current when data “1” is not programmed (data “0” is programmed) in charge accumulation layer 47 of second multilayer 45 (see FIG. 4), and accordingly, the resistance of third diffused region 413 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for first multilayer 441, and current Ids=I101 (5 μA, for example) when a programming operation is performed for first multilayer 441, will be large. The difference ΔIds100 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

In an erasing operation of second multilayer 445, positive charges (hot-holes) are mainly accumulated in second multilayer 445. In a programming operation of second multilayer 445, hot electrons are injected to second multilayer 445 in order to program after the erasing operation.

Namely, when data “1” is programmed in charge accumulation layer 447 of second multilayer 445, it is hard for current (electrons) to flow through fourth diffused region 314 due to negative charges (electrons) in charge accumulation layer 447, and the resistance of fourth diffused region 414 is high. Thus, as shown in FIG. 15, read current Ids is I101 (5 μA, for example) when the programming time is T1 (10 μs, for example). On the other hand, current when data “1” is not programmed (data “0” is programmed) in charge accumulation layer 447 of second multilayer 445 flows even more easily, due to positive charges (holes) in charge accumulation layer 447, through fourth diffused region 414 than current when data “1” is not programmed (data “0” is programmed) in charge accumulation layer 47 of second multilayer 45 (see FIG. 4), and accordingly, the resistance of fourth diffused region 414 is further lowered. Thus, as shown in FIG. 15, read current Ids will be I100 (35 μA, for example, >I0=30 μA; see FIG. 4).

Therefore, the difference ΔIds100 (30 μA, for example) between read current Ids=I100 (35 μA, for example) when no programming operations are performed (data “0” is programmed) for second multilayer 445, and current Ids=I101 (5 μA, for example) when a programming operation is performed for second multilayer 445, will be large. The difference ΔIds100 (30 μA, for example) is larger than the difference ΔIds1 (10 μA, for example; see FIG. 4). Accordingly, it may be easier to discriminate between data “1” and data “0” based on read current Ids, or, it may take less time to discriminate between data “1” and data “0” based on read current Ids.

In the above fourth embodiment, a situation is described in which 2 bits of data are simultaneously erased. However, it is appreciated by those skilled in the art that the block unit data of memory cells 400n, . . . may be simultaneously erased. Then, programming operations of memory cells 400n, . . . are performed after the multi-bits are simultaneously erased. Accordingly, the characteristics of a programming operation of semiconductor memory device 400 will be improved.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to Japanese Patent Application No. 2005-246824. The entire disclosure of Japanese Patent Application No. 2005-246824 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A semiconductor memory device comprising:
a first diffused region disposed within a semiconductor substrate;
a gate dielectric spaced apart from the first diffused region, and overlying the semiconductor substrate;
a gate electrode overlying the gate dielectric;
a first multilayer disposed between the first diffused region and the gate dielectric, and overlying the semiconductor substrate; and
a third diffused region disposed adjacent to the first multilayer within the semiconductor substrate, and doped with dopant at a lower concentration than the first diffused region,
the first multilayer accumulating a first charge, and subsequently accumulating a second charge having a polarity that is opposite to the first charge, in a programming operation.

2. A semiconductor device according to claim 1, wherein the semiconductor substrate is P-type; the first diffused region is N-type; the third diffused region is either N-type or P-type; the first charge is a negative charge; and the second charge is a positive charge.

3. A semiconductor device according to claim 1, wherein the first multilayer comprises:
a charge accumulation layer accumulating the first charge, and
a dielectric layer insulating the charge accumulation layer from the semiconductor substrate.

4. A semiconductor device according to claim 1, further comprising:
a second diffused region disposed on the opposite side of the first diffused region within a semiconductor substrate;
a second multilayer disposed between the second diffused region and the gate dielectric, and overlying the semiconductor substrate; and
a fourth diffused region disposed adjacent to the second multilayer within the semiconductor substrate, and doped with dopant at a lower concentration than the second diffused region,
the second multilayer accumulating a first charge, and subsequently accumulating a second charge having a polarity that is opposite to the first charge, in a programming operation.

5. A semiconductor device according to claim 4, further comprising:
a first voltage applying section applying a gate voltage for the gate electrode, and
a second voltage applying section applying a source voltage for one of the first diffused region and the second diffused region, and applying a drain voltage for the other thereof.

6. A semiconductor device according to claim 5, wherein:
the first voltage applying section applies a positive voltage as the gate voltage in an erasing operation;
the second voltage applying section applies a zero voltage as the source voltage, and applies a positive voltage as the drain voltage, in an erasing operation.

7. A semiconductor device according to claim 5, wherein:
the first voltage applying section applies a zero voltage as the gate voltage in an erasing operation;
the second voltage applying section applies a negative voltage as the source voltage, and applies a positive voltage as the drain voltage, in an erasing operation.

8. A semiconductor device according to claim 5, wherein:
the first voltage applying section applies either a zero voltage or a negative voltage as the gate voltage in an erasing operation;
the second voltage applying section respectively applies a zero voltage and a positive voltage as the source voltage and the drain voltage in an erasing operation, or, respectively applies an open condition and a positive voltage as the source voltage and the drain voltage in an erasing operation.

9. A semiconductor device according to claim 5, wherein:
the first voltage applying section applies either a zero voltage or a negative voltage as the gate voltage in an erasing operation;
the second voltage applying section applies a positive voltage as the source voltage, and applies a positive voltage as the drain voltage in an erasing operation.
